(19) United States
(12) Patent Application Publication
(10) Pub. No.: US 2023/0234094 A1
(43) Pub. Date: Jul. 27, 2023

(54) VACUUM TREATMENT APPARATUS

(71) Applicant: EVATEC AG, Trübbach (CH)

(72) Inventors: Rico BENZ, Montlingen (CH); Martin DÜTSCHLER, Trübbach (CH); Josef STEINKELLER, St. Gallen (CH); Daniele ZORZI, Eschenbach (CH); Jörg PATSCHEIDER, Meilen (CH); Stephan VOSER, Buchs (CH); Pierre MATTEACCI, Flums-Hochwiese (CH)

(21) Appl. No.: 18/001,647

(22) PCT Filed: May 19, 2021
(86) PCT No.: PCT/EP2021/063358

§ 371 Date: Dec. 13, 2022

(30) Foreign Application Priority Data
Jun. 17, 2020 (CH) 00719/20

(51) Int. Cl. B05D 1/00; B05D 3/04; B05D 3/02

(52) U.S. Cl. CPC B05D 1/60; B05D 3/0493; B05D 3/0218

(57) ABSTRACT

So as to perform a vacuum surface treatment on a workpiece at a predetermined temperature, which is different from a temperature to which the surface is exposed during the vacuum surface treatment, the workpiece is conveyed in a conveyance direction along one or more than one station group including one or more than one tempering station and of a single treatment station.

The present invention departs from the following problem:

In the art of vacuum treating surfaces of workpieces it is often desired to hold the surface of the workpiece, during being vacuum treated, on a temperature which is different from the temperature to which the surface is exposed during the vacuum treatment. A specific temperature of the workpiece surface may be desired e.g. for establishing a desired adhesion of a deposited coating, for establishing a desired growth mode of the coating, for achieving a desired deposition rate on the workpiece. This problem may occur e.g. in the art of reactive and of non-reactive PVD, e.g. of reactive or non-reactive sputter deposition, of reactive or non-reactive evaporation-deposition, of CVD, e.g. of PECVD, of thermal CVD, further of polymer-layer deposition as of plasma enhanced polymer deposition or of thermal polymer-layer deposition, of ALD etc.

One solution of this problem in a vacuum surface treatment apparatus is to provide, in the reaction space of a treatment station, some tempering equipment specifically effective on the surface of the workpiece. This, to hold the surface to be treated on a desired surface temperature while, simultaneously, a different temperature prevails in the reaction space of the treatment-station. Such different temperature may be established e.g. for reacting a reactive gas in the reaction space at a specific reaction temperature, for accelerating such reaction or for accelerating adherence of a precursor gas to the surface of the workpiece, may be caused by a plasma exploited in the reaction space of the treatment-station, may be established by the temperature of a monomer gas which is supplied to the reaction space for polymerisation etc.

### Definition

Throughout the description and claims of the present application we understand under a “reactive gas” a reactive gas as commonly known to the skilled artisan in context with PVD and CVD processing but additionally precursor gases as applied in ALD deposition processes and monomer gases as applied in the art of depositing polymer layers on workpieces.

It is an object of the present invention to provide an alternative vacuum treatment apparatus and an alternative method of vacuum treating surfaces of workpieces and an alternative method of manufacturing vacuum treated workpieces.

This is achieved according to the present invention by a vacuum treatment apparatus comprising a vacuum recipient and, in the vacuum recipient, a workpiece conveyer arrangement which is driven by a controlled step-drive arrangement and which comprises at least two workpiece carriers.

The workpiece conveyer arrangement may thereby comprise or consist of a band conveyer, a ring-shaped conveyer, a circular disk-shaped conveyer, a cylindric conveyer, a cone-body shaped conveyer, may comprise one or more than one reciprocating robots, mutually handling the workpiece carriers. Generically, the workpiece conveyer arrangement may convey the workpiece carriers along any desired shape of conveyance path.

Coupled to the vacuum recipient there is further provided at least one station-group consisting, on one hand of one or more than one tempering-station and, on the other hand, of one single treatment-station.

The one single treatment-station is directly neighbouring the at least one tempering-station.

Further, the one single treatment-station is located subsequent the at least one tempering-station considered in the conveyance direction of the workpiece conveyer arrangement.

Thus, the one single treatment-station is the last station of the station group passed by a workpiece carrier and a tempering-station is the first station of a station-group passed by the workpiece carrier in conveyance direction.

The workpiece conveyer arrangement and the step-drive arrangement are constructed to convey the workpiece carriers by one or more than one steps in the conveyance direction simultaneously and simultaneously into alignment with the at least one tempering-station and, respectively, with the one single treatment-station of the at least one station-group. After one step or after more than one steps of the workpiece conveyer arrangement, the workpiece carriers are aligned with the at least one tempering-station and as well with the one single treatment-station of the at least one station-group.

A fixed number of more than one steps of the step-drive arrangement may be exploited to move the workpiece carriers simultaneously and simultaneously into alignment with the addressed stations.

Thus, for a band conveyer, a ring-shaped conveyer, a circular disk-shaped conveyer, a cylindric conveyer, a cone-body shaped conveyer, the step-drive arrangement may comprise a single step-drive. The workpiece conveyer arrangement may nevertheless comprise one or more than one reciprocating robots, e.g. mutually handling the workpiece carriers in the conveyance direction. For driving one or more than one reciprocating robots, comprised in the workpiece conveyer arrangement, the step-drive arrangement may comprise the respective number of mutually synchronized step-drives.

Each of the at least two workpiece carriers is movable by a tempering-station-drive into and from a tempering position relative to the at least one tempering-station when aligned with the at least one tempering-station of the at least one station-group.

Each of the workpiece carriers is movable by a treatment-station-drive into and from a treatment position relative to the one single treatment-station when aligned with the one single treatment-station of the at least one station-group.

### Definition

We understand under the term “tempering” cooling or heating.
We understand under the term “inverse tempering” heating if tempering is cooling and cooling if tempering is heating.
We understand under the term “workpiece” one single piece or more than one single pieces. More than one single pieces are carried on a common workpiece carrier and are thus simultaneously treated in the at least one tempering-station and, respectively, in the one single treatment-station. The workpiece may be a workpiece body or may be a workpiece body having a surface which is the surface of a layer or of a layer system on the workpiece body.
We understand under a “step-drive arrangement” an arrangement of one or more than one step-drives which, in combination, generate a movement consisting of consecutive periods of a stand-still phase and of a conveyance phase, which consecutive periods are equal.
We understand under “a controllable source of thermal energy” and under a “controllable sink of thermal energy” a heater arrangement which provides, in a controlled manner, a heat flow into the reaction space of a treatment-station in which a workpiece is to be treated, and, respectively, a cooler arrangement which provides in a controlled manner a heat flow from the reaction space of a treatment-station in which a workpiece is to be treated.

By means of the at least one tempering-station the surface of the workpiece on the workpiece carrier is brought towards a temperature which is desired for treating the surface of the workpiece in the subsequent one single treatment-station.

Tempering is cooling if the desired temperature of the surface of the workpiece for treating in the single treatment-station is lower than the temperature which is prevailing in the reaction space of the single treatment-station during the treatment.

Tempering is heating if the desired temperature of the surface of the workpiece for treating in the single treatment-station is higher than the temperature which is prevailing in the reaction space of the single treatment-station during treatment.

The temperature prevailing in the reaction space, to which the surface of the workpiece is exposed in the reaction space, is different from the temperature of the surface of the workpiece as it becomes exposed to the reaction space, which surface temperature is dependent and set by the controlled tempering in the tempering-station.

The temperature to which the workpiece is tempered may be lower than the desired temperature of the surface of the workpiece for treating in the single treatment-station, if tempering is cooling and may be higher than the addressed desired temperature, if tempering is heating, thereby taking into account a heat transfer from or onto the workpiece, as it is conveyed from the tempering-station towards and into the treatment-station.

Thus the at least one tempering-station of the apparatus according to the invention is configured to heat or to cool a workpiece in the tempering-station to such a temperature that the heated or cooled workpiece, once conveyed from the at least one tempering-station into the treatment-station, enters the treatment-station with a surface temperature which is different from the temperature the addressed surface is exposed to in the treatment-station by a desired, selected amount.

In one embodiment of the apparatus according to the invention the desired, the selected amount is at least 50° C.

In one embodiment of the apparatus according to the invention the desired, selected amount is at least 100° C.

It has to be noted that the artisan skilled in the art of vacuum processing workpieces, decides about and thus knows
the treatment process to be performed in the treatment-station of the apparatus according to the invention and thus the temperature to which the surface of a workpiece treated therein is exposed to;
the characteristics of the treatment of the workpiece surface by such treatment in the treatment-station in dependency of the temperature of the surface being treated

and thus may establish by which temperature-amount the surface of a workpiece shall be different from the temperature the addressed surface is exposed to in the treatment-station. He configures and establishes control of the tempering-station in a manner, that the addressed temperature amount is reached.

A desired treatment result of the vacuum treatment in the treatment-station of the apparatus according to the invention, worth providing the at least one tempering-station downstream the treatment-station of a station-group, is achieved if, by the addressed tempering, the surface of the workpiece entering the treatment-station is at least 50° or even at least 100° C. different from the temperature to which the addressed surface is exposed in the treatment-station and thus the temperature amount as addressed is at least 50° C. or even at least 100° C.

As examples, and considering layer deposition:

In PVD layer deposition technique a considerable increase of deposition rate may customarily be achieved by setting the surface, on which a layer is to be deposited, several 100° higher than the temperature of the PVD process.

For polymer-layer deposition, dependent on the type of monomer, a temperature of the workpiece surface to be polymer coated of at least 100° C. bellow or above the temperature of the monomer inlet into the treatment chamber may significantly increase the polymerisation rate and thus the layer deposition rare.

The fact, that the apparatus comprises workpiece carriers which are movable by a tempering-station drive and a by a treatment-station drive respectively into the tempering position and into the treatment position, leads to a high flexibility as to how the vacuum coupling of the treatment-station and of the tempering-station coupled to the overall vacuum recipient is to be tailored.

In one embodiment of the vacuum treatment apparatus according to the invention, the single treatment-station comprises a gas feed arrangement which is connected or connectable in gas-flow communication with a gas supply containing a reactive gas.

In one embodiment of the vacuum treatment apparatus according to the invention, the single treatment-station is operationally connected to a controllable source of thermal energy or to a controllable sink of thermal energy for practising a desired treatment process.

In one embodiment of the vacuum treatment apparatus according to the invention a reaction space to which the workpiece carrier is exposed in the single treatment-station is sealed as the workpiece carrier is in the treatment position and remains sealed at least up to terminating the treatment process.

Thereby sealing of the reaction space may be realized in different manners, e.g. by sealing cooperation of the workpiece with parts of the single treatment-station and/or by sealing cooperation of the workpiece carrier with parts of the single treatment-station and/or by sealing cooperation of the workpiece conveyer arrangement with parts of the single treatment-station and/or by sealing cooperation of parts of the single treatment-station.

In one embodiment of the vacuum treatment apparatus according to the invention the single treatment-station comprises a pumping port connectable or connected in flow communication with a pump.

In one embodiment of the vacuum treatment apparatus according to the invention the single treatment-station is a layer deposition station, particularly a polymer-layer deposition station, particularly exploiting a monomer, which polymerizes on a surface at an increasing rate as the temperature of the surface drops. Thereby a gaseous monomer may be fed into the treatment-station at a temperature at or above 100° C. and the workpiece is tempered to such temperature that it enters the treatment-station with a surface temperature of 0° C. or lower. Thus, the amount as desired becomes at least 100° C.

In the single treatment-station not only the respective workpiece having been tempered is surface-treated, but also e.g. the surfaces of the walls of the treatment-station which are exposed to the reaction space of the single treatment-station. So as to prevent these surfaces and other surfaces in the single treatment-station exposed to the reaction space to be treated similarly or even equally to the surface of the workpiece, e.g. with similar adherence, similar deposition rate, similar density of layer material, similar growth mode of the layer etc., in one embodiment of the vacuum treatment apparatus according to the invention, at least a part of the walls of the single treatment-station, comprising surfaces exposed to the reaction space, are provided with an inverse-tempering arrangement. As was addressed above, such inverse-tempering arrangement is one or more than one cooler if tempering is heating and is one or more than one heater if tempering is cooling.

In one embodiment of the vacuum treatment apparatus according to the invention, in the tempering position, a sealed tempering space is defined in the tempering-station and, in a further embodiment of the apparatus according to the invention, the tempering-station comprises a pumping port connectable or connected in gas flow communication to a pump.

Sealing of the tempering space may be realized in analogy to sealing of the reaction space, as the workpiece carriers are simultaneously moved into tempering position, and, respectively, into treatment position. Thus, sealing of the tempering space may be realized in different manners, e.g. by sealing cooperation of the workpiece with parts of the tempering-station and/or by sealing cooperation of the workpiece carrier with parts of the tempering-station and/or by sealing cooperation of the workpiece conveyer arrangement with parts of the tempering-station and/or by sealing cooperation of parts of the tempering-station. Such a sealing prevents the atmosphere within the vacuum recipient to be possibly contaminated by gaseous products freed during the tempering operation. Such gaseous products may be removed by pumping from the sealed tempering-station prior to unsealing. Sealing of the tempering space needs not be realized equally to sealing of the treatment space.

One embodiment of the vacuum treatment apparatus according to the invention comprises more than one of the addressed station-group, each comprising the at least one tempering-station and of the one single treatment-station. These station-groups are located one behind the other considered in the conveyance direction of the workpiece conveyer arrangement, are particularly located directly one behind the other, i.e. without a further station in between or indirectly with one or more than one further station in between. Considered in the addressed conveyance direction, each one single treatment-station of a station-group is preceded by one or more than one tempering-station of the same station-group. If the station-groups are located directly one behind the other, each one single treatment-station of one station-group is directly succeeded by one or more than one tempering-station of the next station-group. The number of the workpiece carriers on the workpiece conveyer arrangement is at least equal to the sum of the number of tempering-stations of the more than one station-groups and of the number of the one single treatment-stations of the more than one station-groups. Thereby and in one embodiment of the embodiment just addressed the more than one station-groups are equal or at least some of the more than one station-groups are different from others of the more than one station-groups. E.g. at least some of the one single treatment-stations of the more than one station-groups may be constructed to operate different vacuum surface treatments. Nevertheless, in one embodiment, especially if the more than one station-groups are located directly one behind the other-without intermediate further station—the one single treatment-stations of the more than one station-groups are constructed to operate the same vacuum surface treatment. Also in this case, some of the more than one station-groups may be different from others by the fact that they operate different tempering ahead equal treatments i.e. tempering in one of the station-groups may be controlled on one temperature, whereas tempering in another of the station-groups is controlled on another temperature.

Please bear in mind, that if, as addressed, the workpiece conveyer arrangement is driven in one conveyance direction by a step drive arrangement as defined, the throughput rate of the apparatus (workpiece output from the apparatus per time unit) is independent from the number of stations served by the workpiece conveyer arrangement. The throughput rate is defined by the period length of the step drive arrangement which acts in fact like a machine clock. If the workpiece carriers are step moved in conveyance direction simultaneously in alignment with the tempering-stations and, respectively, with the one single treatment-stations by more than one movement steps of the workpiece conveyer arrangement, then the throughput rate is dependent from the addressed period multiplied by the number of steps exploited to move the workpiece carriers from alignment with one station into alignment with the next station. The number of steps to do so is constant, and one may say that, in this case, the repetition frequency of the movement steps of the workpiece conveyer arrangement is the repetition frequency of the step drive arrangement divided by the addressed number.

In the time span during which the tempered workpiece is exposed to the treatment in the one single treatment-station e.g. coated with a coating material comprising a reactive gas, the temperature of the surface of the workpiece, starting from an initial temperature, which is dependent from the result temperature of the tempering and is possibly altered during the transport from the tempering-station to the single treatment-station, migrates towards the temperature prevailing in the reaction space of the single treatment-station. If it is desired to have the temperature of the surface of the workpiece to be coated and being coated maintained in a narrow range with respect to such initial temperature, it might not be possible to terminate a desired treatment of the surface of the workpiece at a desired surface temperature or nearby such desired temperature, in one single treatment-station. E.g. it might not be possible to apply in one single treatment-station, tailored as a layer deposition station, a layer of a desired thickness.

Thus, a desired treatment, in the addressed embodiment, is reached by exposing the workpiece subsequently to more than one tempering/treatment station-group, without harming the throughput of the apparatus.

Moreover, providing more than one of the addressed station-groups may be exploited to treat the surface of the workpiece by different vacuum treatment processes, as long as the tempering timespans at all the tempering stations of the more than one station-groups are equal and are also equal to the treatment time spans at all single treatment-stations of the more than one station-groups.

It has to be noted, that by providing more than one succeeding station-groups as addressed, the single station treatment time span at the single treatment-stations of the more than one station-groups as well as the tempering time span at each tempering-station provided in the more than one station-groups may be shortened, which improves the throughput rate of the apparatus.

By providing more than one station-groups the following processings may be realized:
All station-groups have equal numbers of tempering-stations, commonly performing equal tempering results per station-group, and all single treatment-stations of the station-groups perform equal vacuum surface treatments: The result is a substantially homogeneous surface treatment over time e.g. deposition of a layer of substantially homogeneous characteristics along its thickness extent.
At least some station-groups have equal or different numbers of tempering-stations, commonly performing different tempering results per station-group, and all single treatment-stations of the station-groups perform equal vacuum surface treatments: there results a surface treatment structured over time e.g. deposition of a layer of structured characteristics along its thickness extent.
The station-groups have equal or different numbers of tempering-stations, commonly performing different or equal tempering results per station-group, and at least some single treatment-stations of the station-groups perform mutually different vacuum surface treatments: there results a surface treatment structured over time, e.g. deposition of a stack of sublayers with different characteristics along the thickness extent of the stack.

### Definition

We understand under “tempering time span” and under “treatment time span” the respective time spans the workpiece conveyer arrangement resides stationary aligned with the treatment-station and simultaneously, respectively, aligned with the tempering-station. The tempering time span at a tempering-station considered may thus be longer than the time span during which the workpiece is actively tempered in this tempering-station. In analogy, the treatment time span in one single treatment-station considered, may be longer than the time span during which a workpiece is treated in the single treatment-station considered. Nevertheless, all the tempering time spans are equal, and all the treatment time spans are equal and the tempering time spans are equal to the treatment time spans.

In one embodiment of the vacuum treatment apparatus according to the invention, at least one station-group comprises more than one of the tempering-stations, preceding the one single treatment-station. The tempering-stations in the respective station-group are neighbouring each other and are mutually spaced by the same distance by which the at least one tempering-station is spaced from the one single treatment-station. The number of workpiece carriers on the workpiece conveyer arrangement is at least equal to the sum of the number of tempering-stations and of the number of single treatment-stations provided.

The higher that the thermal mass is which is tempered simultaneously with the workpiece, thus the thermal mass of the workpiece itself or the thermal mass of the workpiece and of the respective workpiece carrier, thermally narrowly coupled to the workpiece, or even of the workpiece plus of the workpiece carrier plus of parts of the workpiece conveyer arrangement, the smaller will be the temperature migration of the surface of the workpiece during treatment in the single treatment-station at a given temperature in the reaction space of the single treatment-station. This might be desired, but the trade-off is, that tempering at a predetermined tempering power necessitates more time. By providing more than one tempering-station ahead the one single treatment-station in a station-group, the workpiece and parts thermally narrowly coupled thereto are tempered during a lengthened overall tempering timespan, without harming the throughput rate of the vacuum treatment apparatus. By selectively providing different numbers of tempering-stations at different of the addressed station-groups, the group specific overall tempering time spans may be adapted to different treatment processes performed at respective single treatment-stations e.g. to different layer materials and/or to different layer deposition technics applied by the single treatment-stations of the different station-groups.

The desired number of cycles, tempering and then treating, to which the workpiece surface is exposed may be realised, additionally or alternatively to conveying the workpiece in one conveyance direction along more than one station-group, by cyclically exposing the workpiece to one tempering-station within a station-group and then to the neighbouring one single treatment-station, in that the workpiece conveyer arrangement is constructed to comprise at least one conveyer which is driven by a forwards/backwards step-drive of the step-drive arrangement.

E.g. a workpiece may be exposed to the one tempering-station and then to the neighbouring single treatment-station by a step in one conveyance direction of a conveyer of the workpiece conveyer arrangement. The workpiece is then moved, by inverting the conveyance direction of a further step of the conveyer, back to the addressed tempering-station. Then, by again inverting the conveyance direction of a further step of the conveyer, the workpiece becomes again exposed to the single treatment-station etc. etc. This is achieved by a bidirectional step-drive of or integrated in the step-drive arrangement, a forwards/backwards step-drive acting on the addressed conveyer. Nevertheless, it has to be noted that the throughput rate of the vacuum treatment apparatus and of the methods according to the invention is affected by the number of forwards/backwards cycles established.

In one embodiment of the vacuum treatment apparatus according to the invention the workpiece carriers-once in alignment with a tempering-station-are movable relative to the tempering-station by means of the tempering-station drive, perpendicularly to the conveyance direction, towards and from the tempering position.

Thereby and in one embodiment of the vacuum treatment apparatus according to the invention, the workpiece carriers themselves are movable by the tempering-station drive, perpendicularly to the conveyance direction, towards and from the tempering position, i.e. they are movable with respect to a stationary part of the apparatus, e.g. with respect to the frame of the apparatus.

In one embodiment of the vacuum treatment apparatus according to the invention, the workpiece carriers—once aligned with a single treatment-station—are movable by the treatment-station drive, relative to the single treatment-station, perpendicularly to the conveyance direction towards and from the treatment position.

Thereby and in one embodiment of the vacuum treatment apparatus according to the invention the workpiece carriers are themselves movable by the treatment-station drive, perpendicularly to the conveyance direction, towards and from the treatment position, i.e. they are movable with respect to a stationary part of the apparatus, e.g. with respect to the frame of the apparatus.

In one embodiment of the vacuum treatment apparatus according to the invention the workpiece carriers are moveable by the tempering-station drive and, respectively, by the treatment-station drive, perpendicularly to the conveyance direction towards and from the tempering position and, respectively, towards and from the treatment position by moving at least a part of the workpiece conveyer arrangement—once the workpiece carriers are in alignment, respectively, with a tempering-station and with a single treatment-station.

Because the workpiece carriers, and thus the workpieces, are to be brought towards and from the treatment position and simultaneously, respectively, towards and from the tempering position, they may commonly be moved towards and from these positions by moving the workpiece conveyer arrangement, perpendicularly to the conveyance direction, once they are respectively aligned with a tempering-station and the single treatment-station.

In one embodiment of the vacuum treatment apparatus according to the invention, the workpiece carriers are movable relative to the tempering-station by the tempering-station drive towards and from the tempering position by moving at least a part of the tempering-station perpendicularly to the conveyance direction (W) towards and from the workpiece carrier (17), once the respective workpiece carrier is aligned with a tempering-station.

Thereby at least a part of the tempering-station is driven towards and from the workpiece carrier, establishing a movement of the workpiece carrier towards and from the tempering position, relative to the tempering-station.

In one embodiment of the vacuum treatment apparatus according to the invention, the workpiece carriers are movable relative to the single treatment-station by the treatment-station drive towards and from the treatment position by moving at least a part of the single treatment-station, perpendicularly to the conveyance direction, towards and from the workpiece carrier, once the respective workpiece carrier is aligned with a single treatment-station.

Thereby at least a part of the single treatment-station is driven towards and from the workpiece carrier, establishing a movement of the workpiece carrier towards and from the treatment position relative to the single treatment-station.

In one embodiment of the vacuum treatment apparatus according to the invention, the workpiece carriers comprise contact areas for supporting a workpiece which contact areas provide thermal isolation of the workpiece from the workpiece carrier.

Thereby it is predominantly the thermal behaviour of the workpiece which becomes determining the time course of the workpiece temperature as the workpiece is exposed to a tempering-station and to the single treatment-station.

In one embodiment of the apparatus according to the invention, additionally or alternatively to thermally isolating the workpieces from the respective workpiece carriers, the workpiece carriers and/or the workpiece conveyer arrangement comprise mutual contact areas which provide thermal isolation of the workpiece carrier from the workpiece conveyer arrangement.

This allows to possibly exploit the workpiece carriers as heat storage members for the workpiece, as heat-sinks or heat-sources.

In one embodiment of the apparatus according to the invention, the workpiece carriers comprise—in fact predominantly consist of—a rigid, membrane-like plate, with at least one trough-opening extending, in one further embodiment, over the predominant extent of the membrane-like plate. Thus, the workpiece carriers may even be grid-like.

Thereby, thermal coupling of the workpiece carrier to the workpiece and the thermal mass of the workpiece carrier is reduced. This allows to reduce the tempering time span which is in trade-off with maintaining a desired surface temperature during exposing the workpiece to the treatment in the single treatment-station, so as to achieve a desired treatment effect which possibly necessitates a relatively long treatment time span. E.g. thick layers as possibly desired may not be deposited at the subsequent single treatment-station, tailored as a layer deposition station: Only relatively thin layers may in this case be deposited at a subsequent single layer deposition station, which nevertheless may be compensated by providing more than one succeeding station-group each comprising one or of more than one tempering-stations and one single treatment-station.

One should keep in mind that the initial temperature of the workpiece in the treatment-station may rapidly become insignificant as a layer is deposited on the tempered surface of the workpiece. This due to the growing of the layer thickness. Therefor depositing only thin layers per exposure to a layer deposition station, one of the single treatment-station, and repeating tempering and deposition cycles to achieve a desired thickness of the final layer, allows to control the temperature vs. time course of the surface of the workpiece during all the layer depositions more accurately. One may more generically say, that establishing short treatment time spans and, respectively, equally short tempering time spans lead to an increased accuracy of controlling the temperature of the surface of the workpiece during being treated in the single treatment-station.

Further shortening the tempering timespans and, consequently, shortening the treatment time spans, also repeatedly applied as desired to achieve a desired treatment result of the workpiece, lead to an increased throughput rate of the vacuum treatment apparatus, compared with an apparatus at which the desired treatment result is achieved by one single treatment of relatively long duration i.e. by one single station-group.

In one embodiment of the vacuum treatment apparatus according to the invention, the workpiece carriers are frame shaped and, in a further embodiment, comprise trough openings along the frame periphery.

Besides of providing workpiece carriers with small thermal mass, due to their frame shape and/or their membrane-like small thickness, peripheral through—openings allow gas transition from one side of the workpiece residing on the workpiece carrier to the backside of the workpiece, thereby allowing both-sided tempering of and possibly both sided treating, e.g. layer depositing, on the workpiece.

Although the workpiece conveyer arrangement may be constructed to realize any shape of conveyance path along the one or more than one station-group each of at least one tempering-station and of one single treatment-station, in embodiments of the vacuum treatment apparatus according to the invention, the workpiece conveyer arrangement comprises a ring-shaped conveyer with a center axis or a circular disc-shaped conveyer with a centre axis, which conveyer is rotated around the center axis by the step-drive arrangement.

Thereby the at least one station-group consisting of at least one tempering-station and of the one single treatment-station is arranged facing the one or both flat surfaces of the ring-shaped or of the circular disk-shaped workpiece conveyer. This allows to realize high number of repeated tempering/treatment cycles at a vacuum treatment apparatus with relatively small footprint, compared with an apparatus according to the invention as well, where at the station-groups are arranged e.g. in a linear configuration.

In one embodiment of the vacuum treatment apparatus according to the invention one of the stations provided and facing one of the addressed flat surfaces of the ring-shaped or of the circular disc-shaped workpiece conveyer arrangement is a bidirectional load-lock, e.g. bridging the outside atmosphere of the vacuum recipient and the atmosphere in the inner volume of that vacuum recipient.

In one embodiment of the vacuum treatment apparatus according to the invention, the workpiece conveyer arrangement defines a surface of revolution around a center axis, and the step-drive arrangement rotates the workpiece conveyer arrangement around the center axis. The workpiece carriers are provided tangentially to and along the surface of revolution.

In this embodiment the one or more than one tempering-stations and the one single treatment-station of the at least one station-group are spaced, perpendicularly to tangential planes on the surface of revolution, from the rotational trajectory path of the workpiece carriers, which become aligned to these stations due to the stepped rotational drive of the workpiece conveyer arrangement. The tempering-station drive as well as the treatment-station drive act perpendicularly to the addressed tangential planes, thus, if the surface of revolution is e.g. cylindric, radially with respect to the center axis of the cylinder.

In one embodiment of the vacuum treatment apparatus according to the invention, at least one of opposed surfaces of the workpiece carrier, in the tempering position, faces, via a gap, a tempering surface of the tempering-station, at least a part of the tempering surface being the surface of a heater arrangement or of a cooler arrangement.

In one embodiment of the vacuum treatment apparatus according to the invention, opposed surfaces of the workpiece carrier, in the tempering position, face, via a respective gap, a respective tempering surface of the tempering-station, at least a part of the tempering surfaces being surfaces of heater arrangements or of cooler arrangements.

In one embodiment of the vacuum treatment apparatus according to the invention, the one tempering surface or both tempering surfaces and the respective surface of the workpiece carrier are spaced via the respective gap by an averaged distance d for which there is valid:
0.1 mm≤d≤30 mm,

particularly 0.1 mm≤d≤5 mm.

The distance d is the distance averaged over a midplane along which the workpiece carrier extends.

In one embodiment of the vacuum treatment apparatus according to the invention, a sealed tempering space is defined in the tempering-station and as the workpiece carrier is in the tempering position, and the tempering-station comprises a gas-feed line arrangement dispatching into the tempering space.

By flowing a gas into the tempering space, the pressure therein may be increased, leading to an improved heat conductance in the tempering space. So as to discharge the overpressure in the tempering space, due to the addressed supplying a gas as a heat conduction gas into the sealed tempering space, the tempering space may be vented into the remaining volume of the vacuum recipient by establishing a gas flow communication between the tempering space and the addressed remaining volume with a negligible flow resistance.

If tempering is heating, the tempering-station possibly acts also as a degasser station and by rapidly establishing the flow communication with negligible flow resistance, degassed products are rapidly removed from the tempering space in a flow-burst. This technique is described in the WO 2016/091927 of the same applicant as the applicant of the present application. If contamination of the remaining volume of the vacuum recipient is to be avoided, the tempering space may be surrounded by an enclosure which may be controllably sealed towards the remaining volume of the vacuum recipient. Either this enclosure is pumped via a pumping port to remove degas products prior to venting this enclosure towards the remaining volume of the enclosure or the degas products are pumped by the pump to the remainder volume if no such enclosure is provided, which may be the case if tempering is cooling or if, even if tempering is heating, no undesired gas may spoil the remaining volume. In any case in this embodiment of the apparatus according to the invention no pumping port is provided directly to the tempering space. In an alternative embodiment the tempering space directly communicates with a pumping port and the overpressure in the tempering space is pumped prior to unsealing the tempering space. The former approach has the advantage, that no pumping time is required and thus the entire tempering time span may be exploited for tempering the workpiece.

Thus in one embodiment of the vacuum treatment apparatus according to the invention the tempering space comprises no pumping port and a flow communication from the tempering space to a pumping port is established by unsealing the tempering space and establishing thereby a gas flow communication of negligible flow resistance out of the tempering space.

In one embodiment of the vacuum treatment apparatus according to the invention the tempering-station comprises a pumping port.

In one embodiment of the vacuum treatment apparatus according to the invention, the gas-feed line arrangement to the tempering space is in flow connection with a gas supply containing, in one further embodiment, at least one of helium, hydrogen, argon.

In one embodiment of the vacuum treatment apparatus according to the invention a gas-heater or a gas-cooler is interconnected between the tempering space and the addressed gas supply, along the gas-feed line arrangement.

Thereby the gas is not only exploited for rising the pressure in the tempering space, thereby improving heat conduction between the tempering surfaces and the workpiece residing on the workpiece carrier, but additionally actively contributes, respectively, to heating or cooling i.e. tempering of the surface of the workpiece.

In one embodiment of the vacuum treatment apparatus according to the invention, the single treatment-station comprises a gas feed arrangement for a reactive gas to the reaction space of the single treatment-station. The gas feed arrangement comprises an input line dispatching in the reaction space, a gas input to the input line branching via a controllable valve arrangement to at least two gas supply sources.

By appropriate reciprocal opening—and closing—flow control by the controllable valve arrangement, an ongoing reactive gas supply is ensured also when one of the supply sources has to be exchanged as becoming void.

In one embodiment of the vacuum treatment apparatus according to the invention, the single treatment-station comprises a gas feed arrangement connectable or connected in gas-flow communication with a gas supply containing a reactive gas which reactive gas comprises or consists of a monomer gas with a characteristic according to which the monomer gas polymerizes on a surface with an increasing polymerization rate as the temperature of the surface decreases.

In one embodiment of the vacuum treatment apparatus according to the invention, the single treatment station comprises a gas feed arrangement connectable or connected in gas-flow communication with a gas supply containing a reactive gas which reactive gas does not comprise or does not consist of a monomer gas with a characteristic according to which the monomer gas polymerizes on a surface with an increasing polymerization rate as the temperature of the surface decreases.

Each embodiment of the apparatus according to the invention and as addressed may be combined with one or more than one of the other embodiments if such combination is mutually compatible.

The invention is further directed to a method of vacuum-process treating surfaces of workpieces or of manufacturing workpieces having a vacuum-process treated surface. These methods comprise the steps of:
a) feeding a workpiece into a vacuum atmosphere;
b) conveying the workpiece into a tempering position in an evacuated tempering-station;
c) tempering said workpiece during a tempering time span in said tempering position, by heating or by cooling a surface of the workpiece to a predetermined first temperature;
d) subsequently conveying the tempered workpiece in vacuum into a treatment position in an evacuated treatment-station;
e) treating the addressed surface of the workpiece during a treatment time span in the treating position, thereby exposing the addressed surface to a second temperature;
f) removing the workpiece having said surface vacuum processed from the treatment-station,

thereby selecting the first temperature so that the workpiece, after being conveyed into the treatment position, exhibits a surface temperature which is different from the second temperature by a desired, selected amount, and selecting the tempering time span to be equal to the treatment time span.

One variant of the method according to the invention comprises selecting the addressed amount to be at least 50° C.

One variant of the method according to the invention comprises selecting the addressed amount to be at least 100° C.

One variant of the method according to the invention comprises performing in step c) tempering by more than one locally consecutive tempering steps, each of the tempering steps lasting during the tempering time span.

In one variant of the methods according to the invention the steps b) to e) are repeated at least once.

In one variant of the method according to the invention there is performed a step g) between the steps b) and c) which step g) comprises sealing a tempering pace in the tempering-station to which the addressed surface is exposed.

In one variant of the variant just addressed of the method according to the invention step g) comprises pressurizing the tempering space after having sealed the tempering space.

One variant of the variant just addressed of the methods according to the invention comprises a step h) between the step c) and the step d), whereby the step h) comprises depressurizing the tempering space, particularly by pumping, particularly by directly pumping the tempering space.

One variant of the methods according to the invention comprises a step i) between the step d) and the step e) whereby the step i) comprises sealing a reaction space in the treatment-station to which the addressed surface is exposed.

In one variant of the variant as just addressed of the methods according to the invention, the step i) comprises feeding a reactive gas into the reaction space after having sealed the reaction space.

One variant of the methods according to the invention comprises, at least during the step e), inverse tempering of wall surfaces of the treatment-station which wall surfaces are exposed to the reaction space.

In one variant of the method according to the invention the method is performed making use of the vacuum treatment apparatus according to the invention or according to one or more than one of the embodiments of this apparatus.

One variant of the methods according to the invention comprises performing a step i) between the step d) and the step e), the step i) comprising feeding a reactive gas into the reaction space after the sealing of the reaction space, the reaction gas comprising or consisting of a monomer gas with a characteristic according to which the monomer gas polymerizes on a surface with an increasing polymerization rate as the temperature of the surface decreases.

One variant of the methods according to the invention comprises performing a step i) between the step d) and the step e), the step i) comprising feeding a reactive gas into the reaction space after the sealing of the reaction space, the reactive gas not comprising or not consisting of a monomer gas with a characteristic according to which the monomer gas polymerizes on a surface with an increasing polymerization rate as the temperature of the surface decreases.

Each variant of the methods according to the invention and as addressed may be combined with one or more than one of the other variants if such combinations are mutually compatible.

The vacuum-apparatus and the methods according to the invention are most suited to be used for PVD surface treatment, reactive or not reactive, as e.g. for sputter layer deposition or layer deposition by electron beam or thermal evaporation, to be used for CVD layer deposition, for polymer layer deposition departing from monomers which exhibit increased polymerisation rate as surface temperature increases or as surface temperature decreases, to be used for ALD.

The invention shall now be further exemplified with the help of figures.

The figures show:

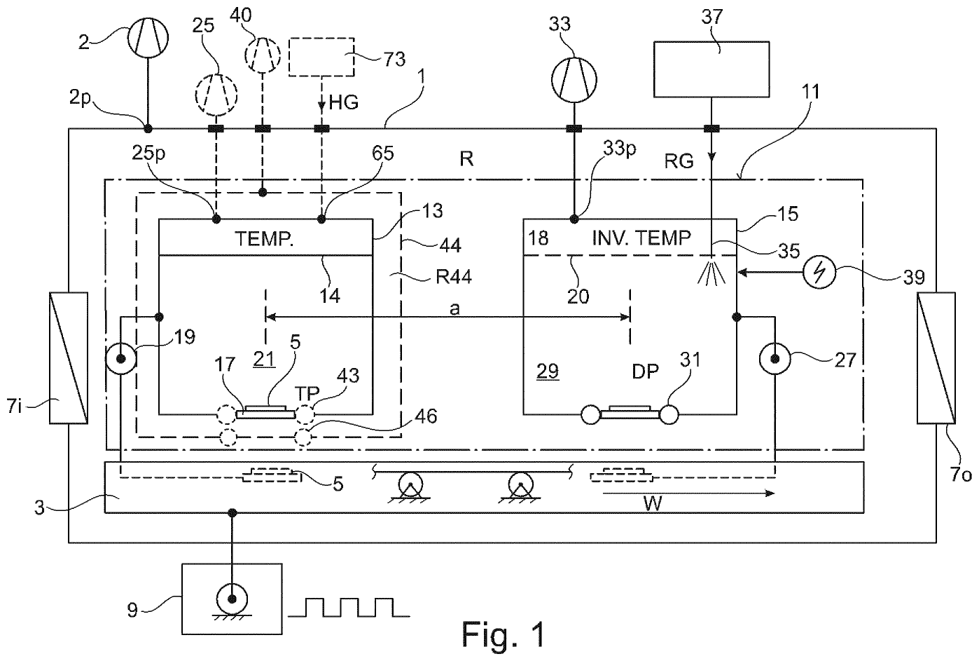

FIG. 1: schematically and simplified the principle of the vacuum treatment apparatus according to the invention in a minimum configuration, suited to practice the methods according to the invention;

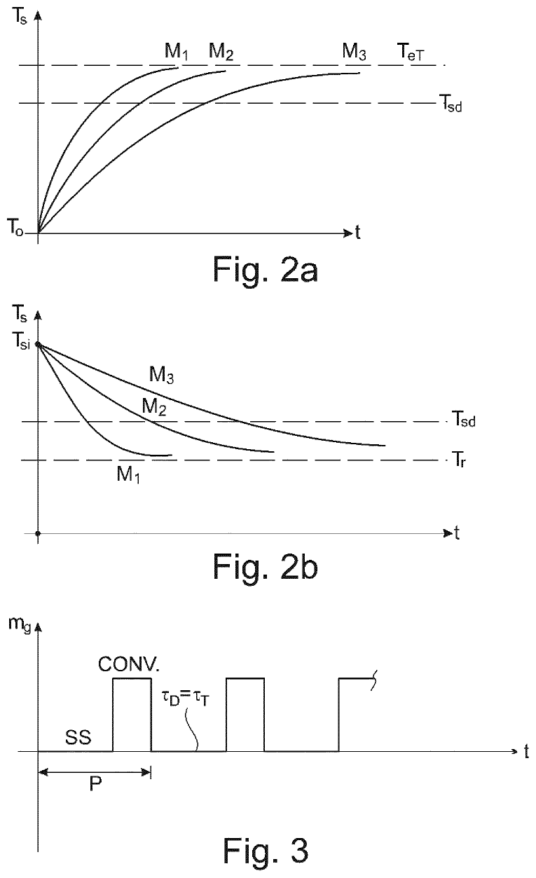

FIG. 2a: qualitatively, the temperature rise as function of thermal mass at a tempering-station of an apparatus according to the invention, where tempering is heating;

FIG. 2b: qualitatively, the temperature drop as a function of thermal mass at a treatment-station of an apparatus according to the invention, where tempering is heating;

FIG. 3: qualitatively, over time, the movement of a step-drive arrangement in an apparatus according to the invention;

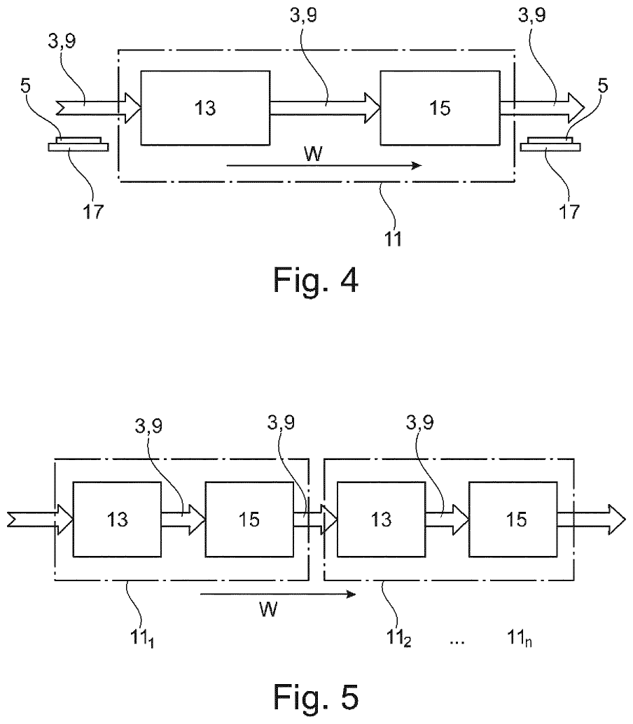

FIG. 4: in a signal-flow/functional-block representation the embodiment of the vacuum treatment apparatus according to FIG. 1;

FIG. 5: in a representation in analogy to that of FIG. 4 a further embodiment of the vacuum treatment apparatus according to the invention;

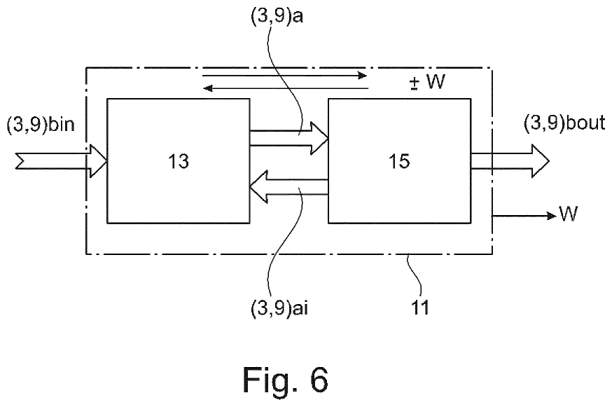

FIG. 6: in a representation in analogy to that of FIG. 4 a further embodiment of the vacuum treatment apparatus according to the invention;

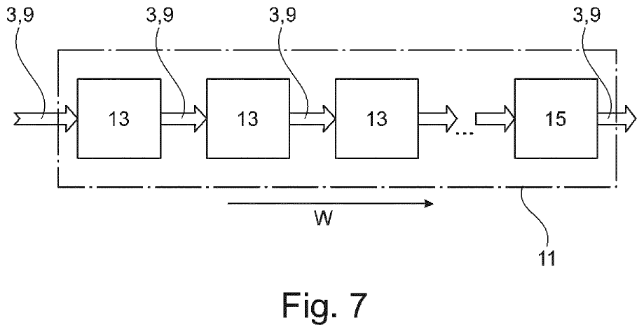

FIG. 7: in a representation in analogy to that of FIG. 4 a further embodiment of the vacuum treatment apparatus according to the invention;

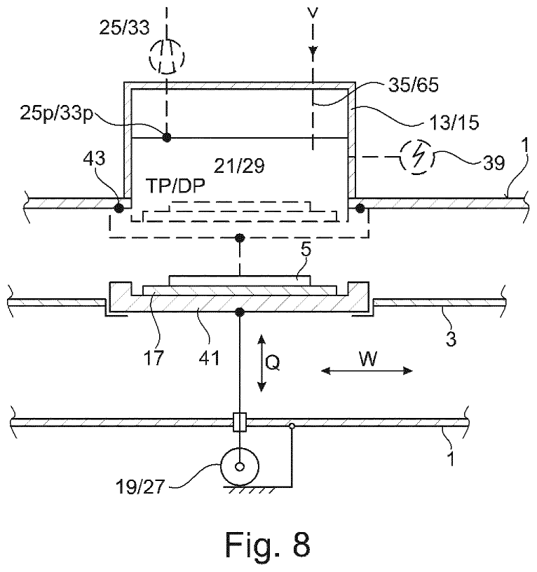

FIG. 8: in a schematic and simplified cross-sectional representation, a station, be it a tempering-station or a treatment-station in one embodiment of the vacuum treatment apparatus according to the invention, wherein a workpiece is moved into and from a tempering position and/or, respectively, into or from a treatment position with respect to a workpiece conveyer arrangement;

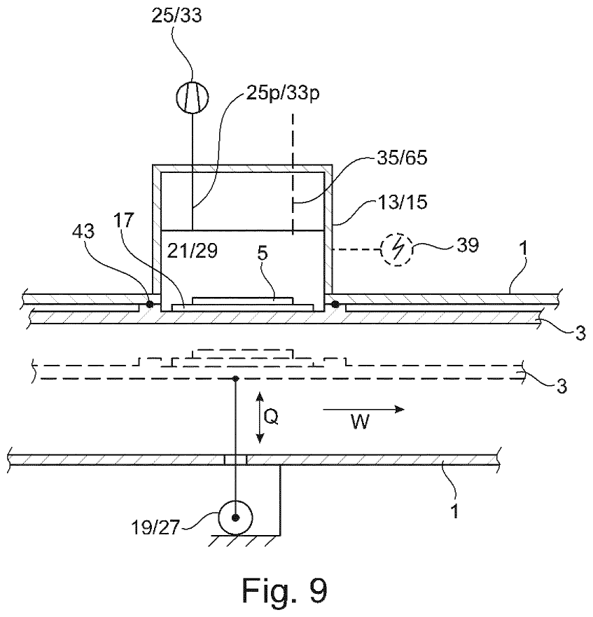

FIG. 9: in a schematic and simplified cross-sectional representation, a station, be it a tempering-station or a treatment-station in one embodiment of the apparatus according to the invention, wherein a workpiece is moved into and from a tempering and/or into and from a treatment position respectively by a workpiece conveyer arrangement;

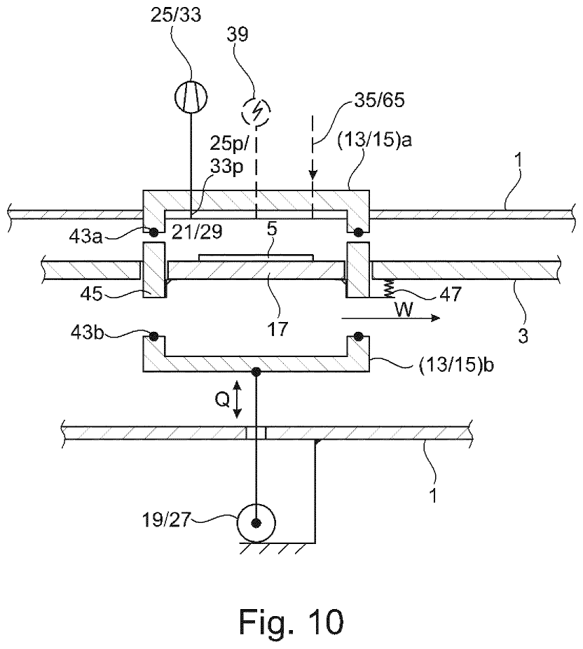

FIG. 10: in a schematic and simplified cross-sectional representation, a station, be it a tempering-station or a treatment-station in one embodiment of the apparatus according to the invention, wherein a workpiece is moved into and from a tempering position and/or into and from a treatment position respectively by moving a part of the respective station;

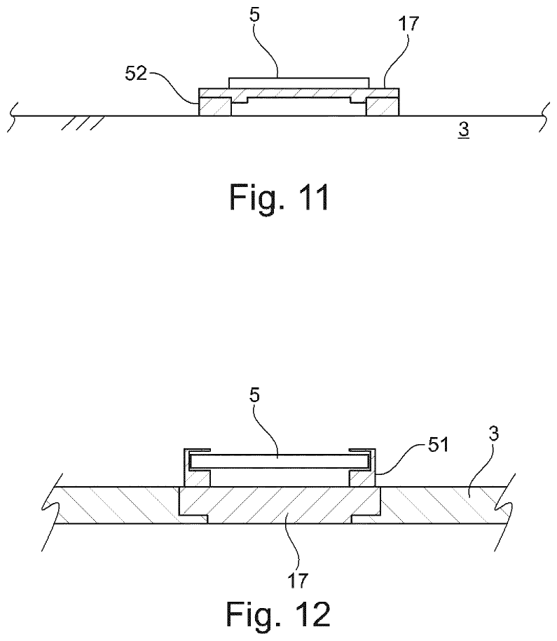

FIG. 11: schematically and simplified a thermal isolation between a workpiece carrier and a workpiece conveyer arrangement in one embodiment of the vacuum treatment apparatus according to the invention;

FIG. 12: schematically and simplified a thermal isolation between a workpiece and a workpiece carrier in one embodiment of the vacuum treatment apparatus according to the invention;

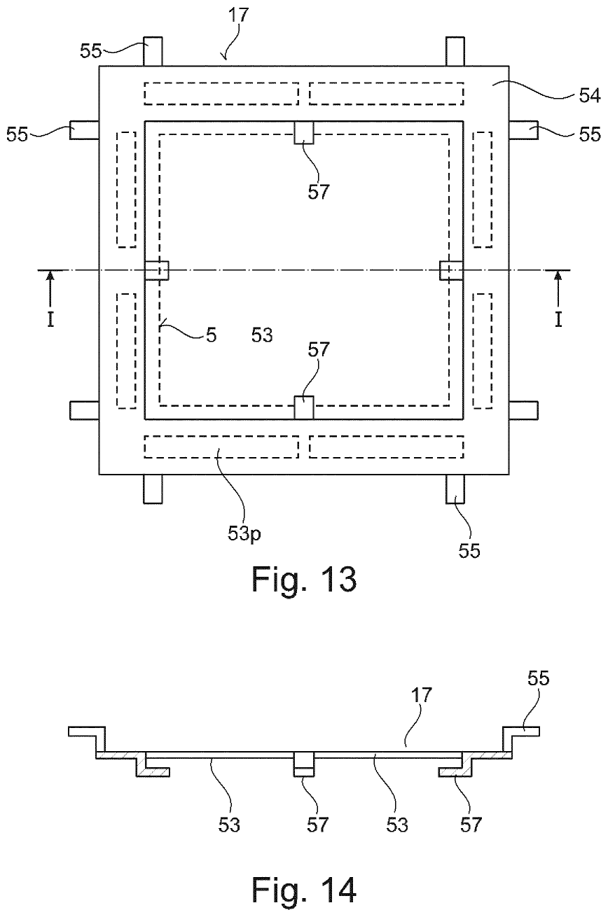

FIG. 13: schematically and simplified a workpiece carrier in an embodiment of the vacuum treatment apparatus according to the invention;

FIG. 14: a cross-sectional representation of the workpiece carrier according to FIG. 13, cut along line I-I;

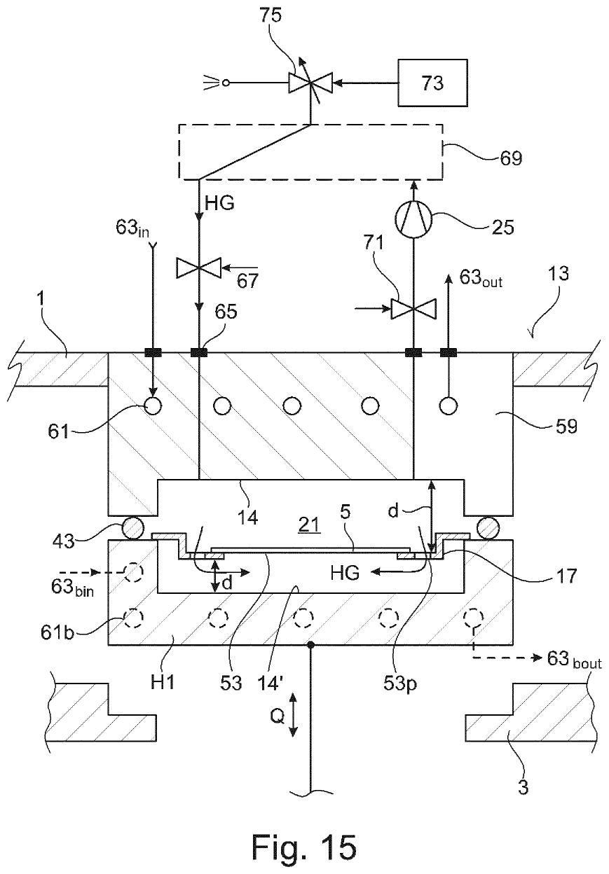

FIG. 15: in a simplified and schematic cross-sectional representation, a tempering-station in an embodiment of the vacuum treatment apparatus according to the invention;

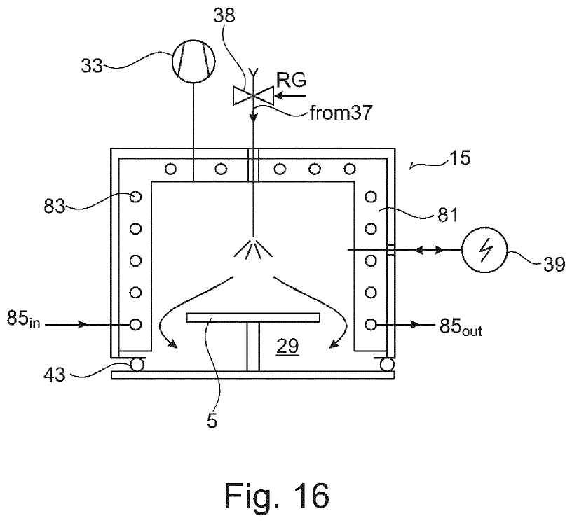

FIG. 16: in a simplified and schematic cross-sectional representation, a treatment-station in an embodiment of the vacuum treatment apparatus according to the invention;

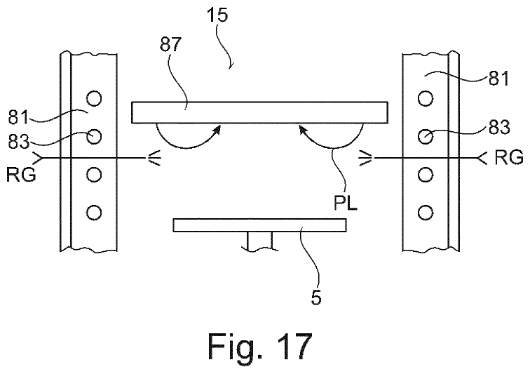

FIG. 17: in a simplified and schematic cross-sectional representation, a part of a treatment-station for sputter coating in an embodiment of the vacuum treatment apparatus according to the invention;

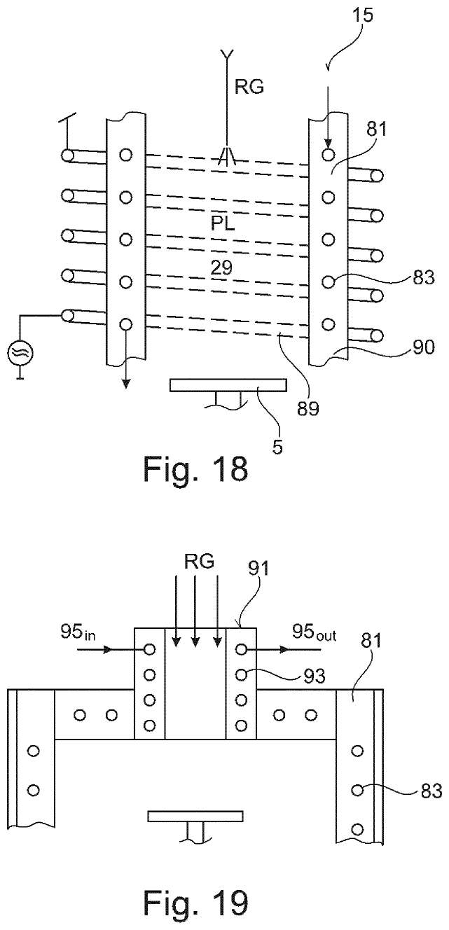

FIG. 18: in a simplified and schematic cross-sectional representation, a part of a treatment-station making use of an inductively coupled plasma in an embodiment of the vacuum treatment apparatus according to the invention;

FIG. 19: in a simplified and schematic cross-sectional representation, a part of a treatment-station making use of thermally activated reactive gas in an embodiment of the vacuum treatment apparatus according to the invention;

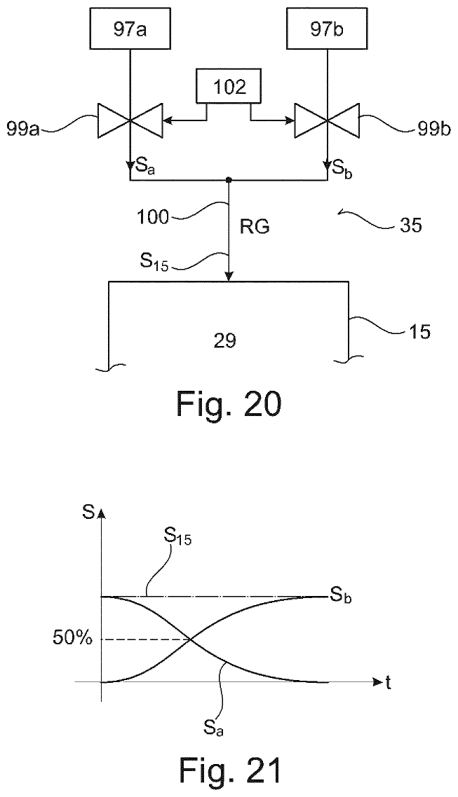

FIG. 20: in a simplified and schematic representation the reactive gas feed to a treatment-station in an embodiment of the vacuum treatment apparatus according to the invention;

FIG. 21: quantitatively the controlled gas flow over time at the reactive gas feed of FIG. 20 in an embodiment of the vacuum treatment apparatus according to the invention;

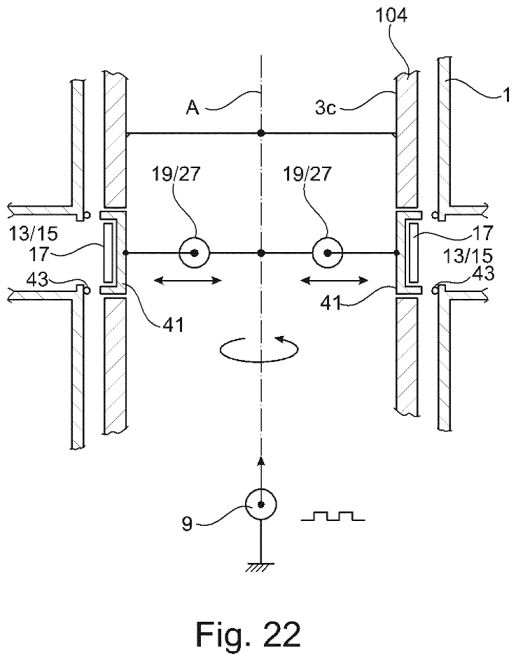

FIG. 22: simplified and schematically, a cross-sectional representation of a part of a cylindrical workpiece conveyer arrangement and its cooperation with the stations in an embodiment of the vacuum treatment apparatus according to the invention;

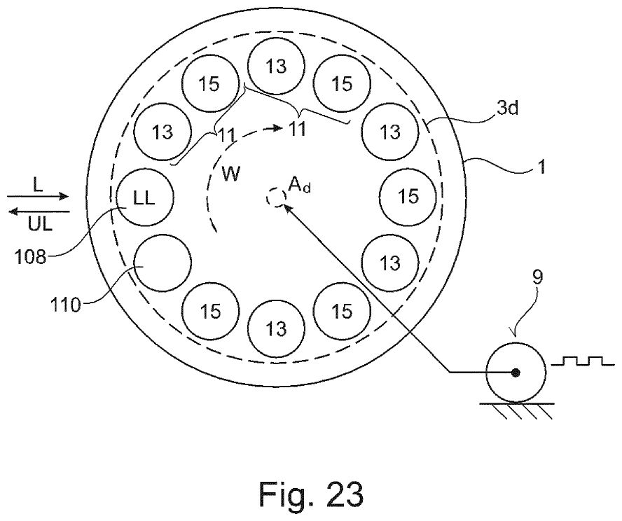

FIG. 23: simplified and schematically, a top view on an embodiment of a vacuum treatment apparatus according to the invention wherein the workpiece conveyer arrangement has the shape of a circular disc.

According to FIG. 1 a workpiece conveyer arrangement 3 resides in a vacuum recipient 1. Workpieces 5 are loaded and unloaded to the vacuum recipient 1 via a load lock arrangement, represented in FIG. 1 by an input load lock 7i and an output load lock 7o, by means of the workpiece conveyer arrangement 3 or by a respectively further conveyer arrangements (not shown in FIG. 1). A step-drive arrangement 9 drives the conveyer arrangement 3. The vacuum recipient 1 has a pumping port 2p which may be, or which is operationally connected to a pump 2.

Coupled to the vacuum recipient 1, e.g. within the vacuum recipient 1, there is provided a station-group 11, shown in dash-dotted line, which consists of at least one tempering-station 13 and of one single treatment-station 15. All the one or more than one tempering-station 13 and the one single treatment-station 15 are mutually spaced by an equal distance “a” considered in the conveyance direction W of the workpiece conveyer arrangement 3. The workpieces 5 are simultaneously conveyed stepwise, by a single or by multiple steps, by the workpiece conveyer arrangement 3, simultaneously and simultaneously into alignment with the one or more than one tempering-station 13 and with the one single treatment-station 15 of the station-group 11, respectively. The number of workpieces 5 simultaneously conveyed by the workpiece conveyer arrangement 3 and spaced by distance “a”, is at least equal to the number of stations 13,15 provided along the workpiece conveyer arrangement 3. Thus, after each stepped movement of the workpiece conveyer arrangement 3 one workpiece is aligned with a tempering-station 13 and one workpiece is aligned with a single treatment-station 15.

On the workpiece conveyer arrangement 3, the workpieces 5 are respectively held on workpiece carriers 17.

Once aligned with the at least one tempering-station of the station-group 11, the workpiece 5 is moved relative to the tempering-station 13 into a tempering position TP, as schematically shown in FIG. 1, by means of a tempering-station drive 19 acting between the workpiece carrier 17 and the tempering-station 13. In dash line the workpiece 5 and the workpiece carrier 17 aligned with the tempering-station 13 are shown remote from the tempering position TP, in solid lines, schematically, in the tempering position TP. After tempering, the workpiece 5 and the workpiece carrier 17 are moved back in the position remote from the tempering position TP by the tempering station drive 19 relative to the tempering-station 13.

In the tempering-station 13 the workpieces are either heated or cooled.

Tempering may be performed in different ways, according to the respective application in which the apparatus according to the invention is involved.
a) If tempering is performed in the atmosphere prevailing in the remaining volume R of the vacuum recipient 1, a tempering space 21 to which the workpiece 5 is exposed in the tempering position TP may not be sealed at all towards the remaining volume R.
b) In one embodiment a gas HG is exploited, which we also call “heat conduction gas”, to rise the pressure in the tempering space 21 with respect to the pressure in the remaining volume R so as to improve heat conductance to or from the surface of the workpiece 5 and from or towards a tempering surface 14. In this case, on one hand, the tempering space 21 is provided with a gas feed arrangement 65 for the heat conduction gas HG, in flow connection with a HG supply 73. On the other hand and in this case the tempering space 21 in the tempering-station 13 is sealed as the workpiece carrier 17 and thus the workpiece 5 are in the tempering position TP. This is schematically shown in FIG. 1 by the seal arrangement 43 in dash line.

As in this latter case an overpressure with respect to the pressure in the remaining volume R is established in the tempering space 21, this overpressure has to be equalized with the pressure in the remaining volume R before unsealing the tempering space 21 at the seal arrangement 43.

This as well may be done according to the respective application in which the apparatus according to the invention is involved.
b1) If tempering is cooling or if tempering is heating but no gas is degassed from the workpiece 5 which would contaminate in an undesired manner the atmosphere in the remaining volume R, equalization of the addressed pressures may be performed by opening the seal arrangement 43 i.e. unsealing the tempering space 21 and directly equalizing the overpressure into the remaining volume R. The remaining volume R is pumped by the pump 2 in flow communication with the pumping port 2p. Thereby rapid and wide opening the sealed tempering space 21 towards the remaining volume R and thereby establishing a flow-connection of a negligible or minimized flow resistance results in a very fast, burst-like pressure equalization, so that practically the total tempering time span, in which the workpiece carrier 17 is in the tempering position TP, may be exploited for tempering purpose. We refer with respect to this equalization approach to the WO2016/091927 of the same applicant as the applicant of the present application.
b2) Especially if tempering is heating and gaseous material is degassed from the workpiece 5 such gaseous material may spoil the atmosphere in the remaining volume R. In this case the tempering space 21 is wide opened by the flow connection of negligible or minimized flow resistance, by opening the seal arrangement 43 into a sealed auxiliary enclosure 44, shown in dash line in FIG. 1. The auxiliary enclosure 44 is pumped by a pump 40, shown in dash line in FIG. 1. The auxiliary enclosure 44 is provided with a large diameter pumping port to the pump 40 allowing a rapid pumping of the combined volumes of the tempering space 21 and of the sealed remaining volume R44 of the auxiliary enclosure 44. It is only after having pumped the combined volume as addressed, that an auxiliary seal arrangement 46 between the remaining volume R44 and the remaining volume R is opened, and the workpiece carrier 17 with the workpiece 5 is removed from the tempering space 21. The auxiliary seal arrangement 46 is schematically and simplified represented in FIG. 1 in dash line.
b3) pressure equalization between the pressurized, sealed tempering space 21 and the pressure in the remaining volume R is performed by providing a pump 25 to a pumping port 25p at the tempering-station 13 and directly to the tempering space 21, a solution which is practiced today by the applicant.

The single treatment-station 15 of the station-group 11 in any case directly follows the tempering-station 13 or follows the last one of more than one tempering-stations 13, considered in the conveyance direction W.

Once aligned with the one single treatment-station 15 of the station-group 11, the workpiece 5 is moved into the treatment position DP relative to the single treatment-station 13 as schematically shown in FIG. 1 by means of a treatment-station drive 27 acting between the workpiece carrier 17 and the single treatment-station 15. In dash line the workpiece 5 and the workpiece carrier 17 aligned with the single treatment-station 15 are shown remote from the treatment position DP, in solid lines, schematically, in the treatment position DP. After treatment, the workpiece 5 and the workpiece carrier 17 are moved back in the position remote from the treatment position DP by the treatment station drive 27.

As was addressed above, the treatment-station 15 may be any kind of station in which the surface of a workpiece is treated by a vacuum process.

In FIG. 1 the single treatment-station 15 is exemplified by a single treatment-station to which a reactive gas RG is fed and thermal energy is supplied to or removed from the reactive gas, as schematically shown at 39.

Whenever the workpiece carrier 17 is in a position in which the workpiece 5 is in treatment position DP, in the embodiment shown in FIG. 1, a reaction space 29 becomes sealed, as schematically shown in FIG. 1 by the seal arrangement 31.

The treatment-station 15 has, in this case, a pumping port 33p which may be, or which is connected to a pump 33.

The gas feed arrangement 35 is in gas flow connection with a supply 37 containing the reactive gas RG. A source or sink of thermal energy 39 operatively coupled to the reaction space 29 of the single treatment-station 15 supplies thermal energy to or, respectively, removes thermal energy from the reaction space 29 dependent on the reactive gas supplied to the reaction space 29.

If the temperature in the reaction space 29 is higher than the desired surface temperature Tsd of the surface of the workpiece 5 to be treated, e.g. to be coated by deposition of material comprising material resulting from reacting the reactive gas RG within the sealed reaction space 29, then tempering in the tempering-station 13 is cooling and the tempering-station 13 comprises a cooler arrangement with the tempering surface 14.

If the temperature in the reaction space 29 is lower than the desired surface temperature Tsd of the surface of the workpiece 5 e.g. to be coated by deposition of material comprising material resulting from reacting the reactive gas RG within the sealed reaction space 29, then tempering in the tempering station 13 is heating and the tempering station 13 comprises a heater arrangement with the tempering surface 14.

In some applications it is desired, on one hand to improve characteristics of the surface treatment e.g. of layer deposition on the surface of the workpiece 5—which is achieved by tempering- and, on the other hand, to avoid such improvement on other surfaces as especially on the surfaces surrounding the and exposed to the reaction space 29. If by the tempering of the workpiece 5 in the tempering-station 13, e.g. an increased deposition rate of layer material on the surface of the workpiece is achieved, such increased deposition rate of layer material on the addressed other surfaces should be avoided. As schematically shown in the block of FIG. 1 representing the single treatment-station 15, in such a case the treatment-station 15 comprises an inverse-tempering arrangement, i.e. if tempering is heating, a cooler arrangement and if tempering is cooling, a heater arrangement as schematically shown by the inverse tempering arrangement 18 and the inverse tempered surface 20.

The thermal behaviour of the surface of the workpiece 5, first in the at least one tempering-station 13 of the station-group 11, then in the directly succeeding single treatment-station 15, depends from the thermal mass M of the workpiece 5 including the thermal masses which are thermally narrowly coupled to the workpiece 5, i.e. possibly of the workpiece carrier 17 and possibly of the workpiece conveyer arrangement 3.

FIG. 2a heuristically and qualitatively shows the thermal behaviour of the thermal mass M over time t during tempering at a single tempering-station 13 and for that case in which the surface of the workpiece 5 shall be tempered to a desired temperature Tsd which is higher than the temperature Tr that the surface will be exposed to when exposed to the treatment in the single treatment-station 15. This case may e.g. occur if a reactive gas RG fed to the treatment station 15 is a monomer gas which polymerizes on a surface with increased polymerization rate as the temperature of the surface increases.

According to FIG. 2a the temperature Ts of the surface of the workpiece 5, starting at the temperature To at which it enters the tempering-station 13, rises towards the desired surface temperature Tsd, desired for improved treating in the single treatment station 15, in dependency from the thermal mass Mx whereby in FIG. 2a there is valid:

M₁<M₂<M₃.

Taking heat losses into account which might occur during the conveyance from the tempering-station 13 towards and into the single treatment-station 15, the temperature TeT to be achieved during tempering by the surface temperature Tₛ is normally selected higher than the desired surface temperature Tsd for surface treatment in the single treatment-station 15.

Departing from the representation of FIG. 2a, FIG. 2b shows again heuristically and qualitatively, the course of the surface temperature Ts in the single treatment-station 15. Departing from an initial surface temperature Tsi, which is dependent from the temperature TeT achieved in the tempering-station 13 and possibly heat losses during the conveyance from the tempering-station 13 to and into the treatment-station 15, the temperature Ts drops towards the temperature Tr and may thereby drop below the desired surface temperature Tsd. Tr is the temperature to which the surface of the workpiece 5 is exposed in the reaction space 29. Thereby one must also consider, that the longer that the workpiece 5 is exposed to the treatment in the single treatment-station 15, the more the result of such treatment might influence the prevailing temperature of the prevailing surface of the workpiece 5. E.g. when a coating or layer is deposited with growing thickness on the surface of the workpiece 5, the surface momentarily exposed to the layer deposition is the surface of the already deposited layer material. The temperature of this momentarily prevailing workpiece surface becomes possibly lower than the temperature Ts of the surface of the workpiece and lower than the desired surface temperature Tsd.

Please note that the considerations according to the FIGS. 2a and 2b are, in analogy, also valid for the case in which Tsd is lower than Tr.

With an eye on FIG. 1 and the explanations thereto, it must be considered, that the throughput rate of the apparatus and of the methods according to the invention is, as schematically shown in FIG. 3, only dependent from the length of the constant periods P of stand-still phases SS and of conveyance phases CONV. of the workpiece conveyer arrangement 3, and thus of the step-repetition frequency of the step-drive arrangement 9. This is valid, if by each single step of the workpiece conveyer arrangement 3 each workpiece carrier 17 is moved to the next station 13 or 15 in conveyance direction. If movement of the workpiece carriers from one station 13 or 15 to the next station 13 or 15 is performed by a number larger than 1 of steps of the workpiece conveyer arrangement 3 then the throughput rate becomes dependent from the length of the addressed period and from the addressed number.

Taking this fact and the thermal behaviours according to FIGS. 2a and 2b in consideration one may conclude:
i. The equal tempering and treatment time spans, respectively in the tempering-station 13 and in the single treatment-station 15, should be short to reach a high throughput rate, because these time spans determine the length of the period P, taking in account, that the length of conveyance phases CONV. may be negligible for a step-drive arrangement;
ii. During a short treatment time span, the resulting treatment effect on the surface of the workpiece e.g. thickness of a deposited coating, is small and the temperature of the prevailing surface of the workpiece 5 is kept nearby the desired temperature Tsd.
iii. So as to realize short tempering time spans, the thermal mass M should be small. This is achieved by small thermal coupling of the workpiece 5 to the workpiece carrier 17, small thermal mass of the workpiece carrier 17 itself, small thermal coupling of the workpiece carrier 17 to parts of the workpiece conveyer arrangement 3.

In FIG. 4 the minimal station-configuration of the apparatus shown in FIG. 1 is represented in an even more schematic and simplified representation by a signal flow/functional block diagram and merely showing the sequence in which the workpieces 5 are step-conveyed towards and through the station-group 11 of one tempering-station 13 and, subsequently, of the single treatment-station 15. This representation allows to properly understand the representations of embodiments of the apparatus and of the methods according to the invention as shown in the following figures and to conclude, with the understanding of FIG. 1, upon their respective more detailed form of realization.

Following the conclusions i. to iii. as addressed above, it might not be possible to realize a desired treatment effect, e.g. a desired coating thickness, in the one tempering-station 13 and the one single treatment-station 15 in the one station-group 11 according to FIGS. 1 and 4.

According to the representation of FIG. 5, maintaining a high throughput rate, achieving any desired degree of treatment effect, e.g. practically any desired thickness of a coating deposited by the treatment on the pre-tempered surface, is realized in one embodiment of the apparatus and of the methods according the invention, by providing more than one of the station-groups 11, shown by 11₁, 11₂, . . . 11ₙ served by the workpiece conveyer arrangement 3 and the step-drive arrangement 9 one after the other in the conveyance direction W, from input- to output load-lock 7i, 7o as of FIG. 1. The throughput rate remains unchanged as merely determined by the step repetition frequency of the step-drive arrangement 9 and the number of steps established to move the workpiece carriers 17 from one station to the next station.

Although the embodiment according to FIG. 5 may be realized to achieve a desired treatment effect e.g. a desired thickness of a coating applied to the workpieces 5, by performing at all the single treatment-stations 15 of all the station-groups 11 provided the same vacuum surface treatment process, by this embodiment, additionally or instead of aiming at a desired overall treatment effect, different treatment processes may be performed, e.g. layer stacks of different materials and/or of different characteristics may be applied on the workpieces 5 as long as the single-station tempering time spans τ_{T} and the single-station treatment time spans ID are equal (see FIG. 3). This is done by respectively altering the vacuum treatment processes in the single treatment-stations 15, of some of the more than one station-groups 11₁, 11₂, 11ₙ and possibly adapting tempering by the tempering-station 13 preceding the respective single treatment-stations 15 in the more than one station-groups 11₁, 11₂, . . . 11ₙ.

Previous, and/or between and/or succeeding one or more than one of station—the groups 11, further vacuum treatment stations, as e.g. degasser- or etching-stations may be provided which are not member of a station-group 11—as succeeding a single treatment-station 15 of a station-group—and which are not shown in the figs.

In another embodiment, shown in FIG. 6 in a representation in analogy to that of FIG. 4, the desired effect of treatment of the surface of the workpiece 5 e.g. of coating a desired layer thickness on the workpiece 5, is achieved by passing the workpiece 5 in a first cycle and within a station-group 11, from the tempering-station 13 to the single treatment-station 15, represented by (3,9)a, then inverting the direction of conveyance W of the workpiece conveyer arrangement 3 by inverting the drive direction of the step-drive arrangement 9 as schematically shown by (3,9)ₐᵢ, to convey the workpiece on the respective workpiece carrier 17 back to the tempering-station 13. These cycles may be repeated as often as necessary to reach a desired final treatment effect, e.g. thickness of the coating. In this embodiment the workpiece conveyer arrangement 3 serves the tempering station 13 as well as the treatment station 15 with a distinct forwards/backwards conveyer and step-drive, whereas first time feed of the workpieces 5 with the respective workpiece carriers 17 to the tempering-station 13 and final removal of the treated workpiece 5 from the single treatment-station 15 is performed by distinct conveyers and step drives (3,9)_{bin} and (3,9)_{bout} which operate mono-directionally towards the tempering-station 13 and, respectively, from the single treatment-station 15.

Although an embodiment according to FIG. 6 may reduce the footprint of the apparatus with respect to an embodiment according to FIG. 5, one should keep in mind that the throughput rate of an embodiment according to FIG. 6 is lowered by the number of repeating cycles. It is only in the apparatus or by the methods in which all the stations 13,15 are served by a one-directional stream of workpieces 5 that the throughput is independent from the number of stations 13,15.

In dependency from the thermal mass M it might be that the tempering time span TT in a single tempering-station 13 does not suffice to reach a desired temperature Tsd.

In such a case two or more than two tempering-stations 13 may precede the one single treatment-station 15 in the or in one of the station-groups 11. This is shown in FIG. 7 in a representation in analogy to those of the FIGS. 4 to 6.

Please note, that the tempering time spans at each of the more than one tempering-stations 13 preceding the single treatment-stations 15 are equal and are equal to the treatment time span in the single treatment-stations 15 of the one or more than one station-groups 11.

Summarizing the processes which may be realized by a vacuum treatment apparatus according to the invention comprising more than one station-groups 11:
All station-groups 11 have equal numbers of tempering stations 13, commonly performing equal tempering results per station-group, and all single treatment-stations 15 of the station-groups 11 perform equal vacuum surface treatments: The result is a substantially homogeneous surface treatment over time e.g. a layer of substantially homogeneous characteristics along its thickness extent.
At least some station-groups 11 have equal or different numbers of tempering-stations 13, commonly performing different tempering results per station-group 11, and all single treatment-stations 15 of the station groups 11 perform equal vacuum surface treatments: there results a surface treatment structured over time e.g. a layer of a layer material but with structured characteristics along its thickness extent.
The station-groups 11 have equal or different numbers of tempering-stations 13, commonly performing different or equal tempering results per station-group 11, and at least some single treatment-stations 15 of the station-groups 11 perform mutually different vacuum surface treatments: there results a surface treatment structured over time, e.g. a stack of sublayers with different characteristics or of different materials along the thickness extent of the stack.

In one embodiment of either the tempering-station 13 or of the treatment-station 15 or of both stations, the workpiece carriers 17 with the workpieces 5 are moved relative to the respective station, into and from the tempering position TP or, respectively, into and from the treatment position DP perpendicularly to the conveyance direction W, by moving the workpiece carriers 17 from and towards the workpiece conveyer arrangement 3. Such an embodiment is schematically shown in FIG. 8. For parts which fulfil the same function as parts which have already been addressed in context with FIG. 1, the same reference numbers are used in FIG. 8.

The workpieces 5 with the workpiece carriers 17 are conveyed by the workpiece conveyer arrangement 3 on a valve member 41 which may be integral with the workpiece carrier 17. The valve member 41 which is shown in the embodiment according to FIG. 8 is only necessary, if the tempering space 21 or, respectively, the reaction space 29 is to be sealed as will be addressed. Once stationary aligned with the respective tempering-station or single treatment-station 13/15, the tempering-station drive 19 or, respectively, the treatment-station drive 27, both addressed by 19/27, lifts the valve member 41 together with the workpiece carrier 17 and the workpiece 5 into the tempering or, respectively, the treatment position TP/DP. Thereby the valve member 41 seals by means of the seal arrangement 43 the reaction space 29—if to be sealed- and, respectively, the tempering space 29, if to be sealed. The valve member 41, the workpiece carrier 17 and the workpiece 5 are shown in the lifted position in dash line. Further the gas feed arrangements 35/65, optional at the tempering-station 13 as well as at the single treatment-station 15, the source or sink of thermal energy 39, optional at the treatment-station 15 and not provided at the tempering station 13, the pumping ports 25p and 33p with the respective pumps 25 and 33, optional at the tempering-station 13 as well as at the single treatment-station 15, are drawn in dash line. Sealing of the reaction space 29—if necessary—, and—if necessary—of the tempering space 21 may be realized in some applications also between the periphery of the workpiece 5 and the respective station 13/15 (not shown). In such a case the valve member 41 may possibly be omitted.

In FIG. 9 a further embodiment of the vacuum treatment apparatus and of the methods according to the invention is shown in a representation in analogy to that of FIG. 8. Because workpiece carriers 17, once simultaneously aligned with the at least one tempering-station 13 and the single treatment-station 15 of a station-group 11 may simultaneously be brought into the tempering position TP and, respectively, into the treatment position DP, the movement of the workpiece carriers 17 with the workpieces 5 relative to the respective stations 13/15 is performed by or at least comprises a respective movement of the workpiece conveyer arrangement 3. In FIG. 9 the position before lifting of the workpiece conveyer arrangement 3, of the workpiece carrier 17 and of the workpiece 5 is shown in dash line, in opposition to FIG. 8. Sealing of the reaction space 29—if necessary—and—if necessary—of the tempering space 21 is established via seal arrangement 43 between the workpiece conveyer arrangement 3 as shown in FIG. 9, or between the workpiece carrier 17 (not shown in the fig.) or between the periphery of the workpiece 5 (not shown in the fig.) and the respective station 13/15.

A further embodiment of the vacuum treatment apparatus and of the methods according to the invention is shown in FIG. 10, in a representation in analogy to those of the FIGS. 8 and 9. Here the movement of the workpiece carrier 17 and thus of the workpiece 5 relative to the respective station 13/15 includes or is performed by a movement of at least a part of the respective station 13/15. A part (13/15)b of the tempering-station 13 or, respectively, of the single treatment-station 15 is moved -Q- towards a frame 45 on the workpiece conveyer arrangement 3. The frame 45 is movable with respect to the workpiece conveyer arrangement 3, biased by a spring arrangement 47, in a direction perpendicular to the conveyance direction W. The part (13/15)b of the tempering-station 13 or, respectively, of the single treatment-station 15 contacts, if necessary via a first seal arrangement 43b the frame 45 and pushes the frame 45 to contact, if necessary via a seal arrangement 43a, the second part (13/15)a of the tempering-station 13 or, respectively, of the single treatment-station 15. Thereby, the tempering space 21—if to be sealed—becomes sealed and/or, respectively, the reaction space 29—if to be sealed—becomes sealed, as the workpiece carrier 17 and thus the workpiece 5 are in tempering position TP or, respectively, in treatment position DP.

As was addressed above the throughput rate may be drastically increased by tailoring the equal treatment time spans ID and tempering time spans TT as short as possible. Whereas the overall time span for treating the surface of the workpiece 5 e.g. to depositing a desired thickness of a coating on the workpiece 5, may be subdivided in short treatment time spans by having the workpiece pass a respective number of station-groups 11 and the overall time span for tempering the surface of the workpiece 5 to the desired temperature Tsd may be subdivided by providing a respective number of consecutive tempering-stations at the station-group 11, with respectively shortened tempering time spans, the time spans for tempering the surface of the workpiece 5 in one or more than one succeeding tempering stations 13 is dependent from the thermal mass M.

FIG. 11 shows schematically and simplified a part of the workpiece conveyer arrangement 3 with workpiece carrier 17 and workpiece 5, wherein a first approach is realized for reducing the thermal mass M i.e. the thermal mass of the workpiece and of equipment tempered together with the workpiece 5. Thereby the workpiece carrier 17 is coupled and held on the workpiece conveyer arrangement 3 in a thermally low coupled manner as schematically shown in FIG. 11 by thermally isolating mutual contact areas 52. It is perfectly known to the skilled artisan, that establishing a low thermal coupling between the workpiece carrier 17 and the workpiece conveyer arrangement 3 may be realized in a lot of different ways as by small mutual contact areas, mutual separation by a gap, etc.

FIG. 12 shows schematically and simplified a part of the workpiece conveyer arrangement 3 with workpiece carrier 17 and workpiece 5 wherein a second approach is realized for reducing the thermal mass M. Here the workpiece carrier 17 is thermally low coupled to the workpiece 5, as schematically represented by thermally isolating contact areas 51. It is perfectly known to the skilled artisan, that establishing a low thermal coupling between the workpiece carrier 17 and the workpiece 5 may be realized in a lot of different ways, as by very small mutual contact areas, mutual separation by a gap, etc.

A further efficient third approach of reducing the thermal mass M is to reduce the mass of the workpiece carrier 17.

According to FIGS. 13 and 14 this is achieved by providing the workpiece carrier 17 as a membrane-like, thin plate 54, which may be of a metal, e.g. of aluminum. FIG. 13 shows schematically a top view on such a workpiece carrier 17 as may be provided in all embodiments of the vacuum treatment apparatus and of the methods according to the invention, as e.g. in the embodiments according to the FIGS. 8 to 10. The workpiece carrier 17 shown in FIG. 13 is, as an example, constructed to carry a square, disk-shaped workpiece 5 shown in dash line. To further reduce the thermal mass of the workpiece carrier 17, beside of making it of a membrane-like, thin plate 54, and as shown in FIG. 14, which is a cross sectional representation along line I-I of the workpiece carrier 17 of FIG. 13, the predominant part of the extent of the workpiece carrier 17 is realized by trough-openings 53. The embodiment according to FIGS. 13 and 14 is frame-shaped with a central-through opening 53 and possibly peripheral through-openings 53p shown in dash line (not shown in FIG. 14). The frame-shaped workpiece carrier 17 is, on one hand, held in the workpiece conveyer arrangement 3 by means of conveyer hooks 55 and, on the other hand, holds the workpiece 5 by workpiece hooks 57. Please note, that in this embodiment, the workpiece carrier 17 is thermally loosely coupled to the workpiece conveyer arrangement 3 (not shown in the FIGS. 13 and 14) via the conveyer hooks 55 and is as well thermally loosely coupled to the workpiece 5, via the workpiece hooks 57. Thus, the approaches according to the FIGS. 11 and 12 are as well applied in the embodiment of FIGS. 13 and 14.

Also having been exemplified for a square workpiece 5, a workpiece carrier 17 according to FIGS. 13 and 14 may be shaped for any shape of workpiece 5, especially for disk-shaped workpieces, disk-shaped circular workpieces as e.g. for wafers, optical lenses etc.

By conceiving the interconnection between the workpiece conveyer arrangement 3, the workpiece carrier 17 and the workpiece 5 according to the principle shown in the FIGS. 11 to 14 the tempering time span TT to reach a predetermined surface temperature of a workpiece becomes practically only dependent from the thermal mass of the workpiece 5 itself, allowing to establish shortest possible tempering time spans TT and thus very high throughput rates.

FIG. 15 shows, schematically and simplified an embodiment of a tempering-station 13 as practiced today with some additional features not practiced today. This embodiment is based on the more generic embodiment of the tempering-station 13 as exemplified in FIG. 8 especially with respect to sealing the tempering space 21 and moving the workpiece 5 into and from the tempering position TP. The wall 59 of the tempering station 13 having its inside surface as a tempering surface 14 exposed to the tempering space 21 is provided with a system of channels 61 for a liquid or gaseous heating or cooling tempering fluid. The system of channels 61 is fed with liquid or gaseous heating or cooling tempering fluid by supply lines 63in and 63out. Whenever the valve member 41, as shown in FIG. 15, is in that position, in which the workpiece 5 is in tempering position TP, the tempering space 21 is sealed by the seal arrangement 43. The workpiece carrier 17 is constructed as was principally addressed in context with FIGS. 13 and 14. If desired to expose both sides of the workpiece 5 to the tempering space 21, the workpiece carrier 17 is provided with the peripheral through openings 53p. Further, the valve member 41 too may be provided with a system of channels 61b supplied by supply lines 63bin and 63bout.

To increase heat transfer from the tempering surface 14 and possibly 14′ of the wall 59 exposed to the tempering space 21 to the workpiece 5 or inversely, the pressure in the sealed tempering space 21 is increased over the vacuum pressure established in the vacuum recipient 1 by pump 25 (see FIG. 1). This is performed by providing the gas feed arrangement 65 dispatching in the tempering space 21 and by feeding a gas HG as e.g. helium, hydrogen or argon into the sealed tempering space 21, controlled by a control valve 67.

To just increase the addressed heat transfer from or to the workpiece 5, it suffices to establish an increased pressure in the tempering space 21 by a static cushion of the gas HG and to vent or pump such overpressure by the pump 25 as shown in FIG. 1 before the seal of the tempering space 21 is disabled.

Nevertheless, as exemplified in FIG. 15, not practiced today but possibly desired for some applications, the gas HG may additionally be exploited as heat sink or heat source with respect to the workpiece 5. To do so the gas HG may be heated or may be cooled in a gas tempering unit 69 prior to be dispatched into the sealed tempering space 21.

The pre-heated or pre-cooled gas HG is in this case circulated along one, or, in the embodiment of FIG. 15 along the upper and the lower surfaces of the workpiece 5 and adds to the respective tempering effect on the respective surfaces of the workpiece 5. In a further, possibly desired embodiment, also exemplified in the embodiment of FIG. 15, the gas HG might be recycled, in that the pump 25 feeds the gas HG back to the gas tempering unit 69 for re-heating or re-cooling, via control valve 71. The gas tempering unit 69 might then be supplied with fresh gas HG from the HG-supply 73 and/or is vented via a control valve 75.

In some embodiments the heated or cooled tempering surfaces 14,14′as of the wall 59 or possibly of the valve member 41 facing the workpiece carrier 17 are spaced from the workpiece carrier 17 by a distance d for which there is valid:
0.1 mm≤d≤30 mm, or even
0.1 mm≤d≤5 mm.

For a workpiece 5 which is plate-shaped like a membrane as shown in FIG. 15 and exhibits two opposed extending surfaces, the distance d is shown in FIG. 15.

Based on the generic representation in FIG. 1, FIG. 16 shows schematically and simplified an embodiment of the single treatment-station 15. Thereby the manner of moving the workpiece 5 into and from the treatment position DP within the reaction space 29, which is in the embodiment of FIG. 16 sealed, and the manner of establishing such sealing of the reaction space 29 whenever the workpiece 5 is in the treatment position DP is only shown in a fundamental representation and may be realized e.g. as shown in the FIGS. 8, 9, 10 and 15. In the embodiment of FIG. 16, a reactive gas RG from the supply 37, containing the reactive gas RG, is fed, via a control valve arrangement 38 into the reaction space 29. In the reaction space 29 the reactive gas RG is reacted whereby thermal energy may be supplied to or may be removed from the reaction space 29 by the source or sink of thermal energy 39.

In the embodiment of FIG. 16, a coating or layer material comprising the reacted reactive gas deposits on a surface of the workpiece 5 which surface has been tempered in the one or in the more than one preceding tempering-station 13 to a desired temperature Tsd for the coating deposition.

So as to avoid that surface areas of the single treatment-station 15 which are exposed to the reaction space 29 are treated equally to the pre-tempered surface of the workpiece 5 in the single treatment-station 15, in the embodiment of FIG. 16 these surfaces areas are inverse-tempered by means of an inverse-tempering arrangement 81.

Thus, if tempering of the surface of the workpiece 5 to be treated in the one or more than one preceding tempering-station 13 is heating, the respective inverse tempering at the single treatment station 15 by the inverse-tempering arrangement 81 is cooling. As schematically shown in FIG. 16 the inverse-tempering arrangement 81 may comprise a system of inverse-tempering channels 83 along those surfaces exposed to the reaction space 29 which shall not be treated, e.g. coated according to the embodiment of FIG. 16, equally to the surface of the workpiece 5. The system of inverse-tempering channels 83 for a heating or for a cooling inverse tempering liquid or gaseous medium is supplied by lines 85in, 85out.

FIGS. 17 to 19 show most schematically, simplified and based on the generic representation of FIG. 16, further examples of single treatment-stations 15 as may be provided in respective station-groups 11. FIGS. 17 to 19 only show a part of the treatment-stations 15.

The treatment station 15 according to the embodiment of FIG. 17 is a magnetron sputter deposition station comprising a target 87. If reactive sputtering is performed, reactive gas RG is reacted by means of the plasma PL of the magnetron sputtering source. Surface areas in the single treatment-station 15 which shall not be coated equally to the tempered surface of the workpiece 5 are equipped with the inverse-tempering arrangement 81 which comprises a cooler arrangement or a heater arrangement, realized e.g. by inverse-tempering channels 83 for an inverse tempering liquid or gaseous fluid.

According to FIG. 18 a Rf induction coil 89 generates an inductively coupled plasma PL in the reaction space 29 of the single treatment-station 15. The induction coil 89 is separate from the vacuum atmosphere in the reaction space 29 by a vacuum tight enclosure 90. A reactive gas RG is fed into the reaction space 29. Surface areas of the vacuum tight enclosure 90 which are exposed to the reaction space 29 are inversely tempered by an inverse-tempering arrangement 81, a heater arrangement or a cooler arrangement, realized e.g. by inverse-tempering channels 83 for an inverse-tempering liquid or gaseous fluid.

In the single treatment-station 15 according to FIG. 19 a reactive gas RG, e.g. a monomer gas, is activated by a heater arrangement 91 as a source of thermal energy as addressed in FIG. 1 by the reference number 39 and polymerizes on the surface of the tempered surface of the workpiece 5. Surface areas in the deposition stations 15 which shall not be coated equally to the tempered surface of the workpiece 5 are equipped with the inverse tempering arrangement 81. The heater arrangement 91 is exemplified by a system of channels 93 for a liquid or gaseous heating medium, supplied by the lines 95in and 95out. The inverse tempering arrangement 81 is realized e.g. by the inverse tempering channels 83 for an inverse tempering liquid or gaseous fluid.

The apparatus and methods by which a vacuum treatment of the surface of a workpiece is performed at a desired temperature of the surface to be treated, may be applied practically to any technique of vacuum treating or—processing surfaces of workpieces, be it e.g. to PVD, CVD, PECVD, ALD, polymer coating etc.

As we have addressed, very short time spans for surface treating e.g. coating deposition, at the single treatment stations 15 may be realized due to the fact that a desired treatment result or effect e.g. a desired coating thickness, may nevertheless be reached namely by successively exposing the respective workpiece to more than one of the station-groups 11, each with a single treatment-station 15. Thereby the treatment at single treatment-stations 15 becomes in fact a partial treatment with respect to the desired final treatment of the surface of the workpiece 5.

Because the thermal mass M to be tempered at the at least one tempering-station 13 may be minimized practically to the thermal mass of the workpiece, and the thermal mass governs the tempering time span at a given tempering power, and final tempering before entering the one treatment-station 15 of a station-group 11 may be realized by successive tempering-stations 13 at such a station-group 11, thus performing each a partial tempering, very short tempering and treatment time spans per respective stations 13/15 may be realized and thus very high throughput rates.

In an embodiment of the apparatus and of the methods according to the invention a constant availability of reactive gas—if used—in the single treatment-station 15 is ensured as schematically and simplified shown in FIG. 20. The reactive gas RG is fed to the treatment-station 15 from at least two supply sources 97a and 97b. Via control valves 99a and 99b the outputs of the supply sources 97a and 97b are led via a common input line 100 to the reaction space 29 of the single treatment-station 15. As qualitatively shown in FIG. 21 the gas supplies Sa from supply source e.g. 97a, once approaching void, is reduced in a controlled manner by the control valve 99a and, simultaneously, the supply Sb from the full supply source 97b is increased in a controlled manner by the control valve 99b in such a manner that the gas supply S15 to the treatment station 15 remains constant. The control valves 99a and 99b are accordingly controlled in mutual dependency by a valve control unit 102.

Thereby an ongoing constant availability of reactive gas RG to the single treatment-station 15 is ensured.

In FIG. 1 the workpiece conveyer arrangement 3 is shown rather as linear workpiece conveyer arrangement, e.g. realized by a band type workpiece conveyer arrangement or, additionally thereto or alternatively thereto, by a chain of handling robots or by single handling robots.

To show, that the vacuum treatment apparatus and the methods according to the present invention may be realized with multiple types of workpiece conveyer arrangements 3 as long as they are driven by a step-drive arrangement 9 as was described, FIG. 22 shows schematically and simplified an embodiment of the vacuum treatment apparatus and of the methods according to the invention, in which the workpiece conveyer arrangement 3 defines a surface of revolution around a center axis A. In the embodiment exemplified in FIG. 22 the surface of revolution is a cylinder surface. Further the embodiment shown in FIG. 22 is, as an example, based on the embodiment shown in FIG. 8. The valve members 41 are arranged along the cylindric wall 104 of the cylindric workpiece conveyer arrangement 3c. The step-drive arrangement 9 rotates stepwise the cylindric workpiece conveyer arrangement around the center axis A so that the valve members 41 and therewith the workpiece carriers 17 and the workpieces (not shown in FIG. 22) become simultaneously aligned with the tempering-stations 13 and, respectively, the single treatment-stations 15, commonly addressed by 13/15 in FIG. 22. The tempering-station drives 19 and the treatment-station drives 27, commonly addressed in FIG. 22 by 19/27 act in radial directions with respect to the center axis A on the valve members 41. More than one system of valve members 41 with the respective radially acting drives 19/27 and respective stations 13/15 may be provided, staggered in the direction of center axis A.

FIG. 23 shows, schematically and simplified an embodiment of the vacuum treatment apparatus and of the methods according to the invention as practiced today. It is based on the machine platform as taught in the WO 2010/105967 from the same applicant as the present application. The workpiece conveyer arrangement comprises a circular disk 3d within the cylindric vacuum recipient 1. Instead of a circular disk 3d the workpiece conveyer arrangement 3 may be shaped as a ring.

The workpiece conveyer arrangement 3d is stepwise driven by the step-drive arrangement 9 around the center axis Ad so that the workpiece carriers (not shown in FIG. 23) residing along a coaxial circle around the axis Ad and along the periphery of the circular disk 3d become simultaneously aligned with the at least one tempering-station 13 and the single treatment-station 15 of respective station group 11. In the embodiment shown in FIG. 23 each station group 11 comprises just one tempering station 13. Nevertheless in other embodiments based on that of FIG. 23, and dependent on the specific application of the apparatus and the methods according to the invention, one or more than one of the station-groups 11 may comprise more than one and possibly different numbers of tempering-stations 13.

Workpieces are loaded on and unloaded from the respective workpiece carriers (not shown in FIG. 23) e.g. via a bidirectional load lock station 108 as represented by the arrows L and UL. The circular, disc-shaped workpiece conveyer arrangement 3d, is stepwise rotated by the step-drive arrangement 9 in one rotational direction as conveyance direction W. The station 110, the last station passed by a workpiece before being unloaded via the bidirectional load lock station 108, may be any kind of vacuum treatment station as needed in a specific application or may be omitted.

Summarizing one may say:

It is desired to expose the surface of a workpiece to a vacuum treatment at a desired surface temperature. This is achieved according to the invention by tempering the addressed surface in at least one tempering-station remote from and directly upstream the vacuum treatment in a treatment-station.

Because no tempering is necessary if the vacuum treatment process itself exposes the addressed surface to the desired surface temperature, there is established by the addressed tempering a temperature of the surface of the workpiece in such a manner, that this surface enters the treatment station with a surface temperature which is different from the temperature to which the surface is exposed during the treatment process by a predetermined, desired temperature difference or temperature amount.

Providing the tempering facilities as described is especially then justified, when the desired temperature at which the surface of the workpiece enters the treatment-station is at least different from the temperature this surface will be exposed to during the treatment process, by a temperature amount of at least 50° C. and even of at least 100° C. If the temperature of the surface, as it enters the treatment station, is too similar to the temperature to which that surface is exposed during the treatment process, then the result with respect to the treatment characteristics on the surface will not be substantially different from those characteristics achieved without tempering, and thus providing the tempering facilities as described are rather not justified.

What is claimed is:

1. A vacuum treatment apparatus, comprising
a vacuum recipient (1);
a workpiece conveyer arrangement (3) in said vacuum recipient, driven by a controlled step-drive arrangement (9) in a conveyance direction (W) and comprising at least two workpiece carriers (17);
at least one station-group (11) coupled to said vacuum recipient (1) and consisting of at least one tempering-station (13) and of one single treatment-station (15), said one single treatment-station (15) being located subsequent said at least one tempering-station (13) in said conveyance direction, said at least one tempering-station (13) and said one single treatment-station (15) being mutually spaced by a distance in said conveyance direction (W);
said workpiece conveyer arrangement (3) and said step-drive arrangement (9) being constructed to convey said workpiece carriers (17) by one or more than one steps in said conveyance direction (W) simultaneously and thereby simultaneously into alignment with said at least one tempering-station (13) and with said one single treatment-station (15);
each of said at least two workpiece carriers (17) being movable by a tempering-station drive (19) into and from a tempering position (TP) relative to said one single tempering-station (13), once aligned with said tempering-station;
each of said at least two workpiece carriers (17) being movable by a treatment-station drive (27) into and from a treatment position (DP) relative to said one single treatment-station (15), once aligned with said one single treatment-station,
said at least one tempering-station being configured to heat or to cool a workpiece in said tempering-station to such a temperature that said heated or cooled workpiece, once conveyed from said at least one tempering-station into said treatment-station, enters said treatment-station with a surface temperature which is different from the temperature said surface is exposed to in said treatment-station by a desired, selected amount.

2. The vacuum treatment apparatus according to claim 1 wherein said desired, selected amount is at least 50° C.

3. The vacuum treatment apparatus according to claim 1 wherein said desired, selected amount is at least 100° C.

4. The vacuum treatment apparatus according to claim 1 wherein said single treatment-station (15) comprises a gas feed arrangement (35) connectable or connected in gas-flow communication with a gas supply (37) containing a reactive gas.

5. The vacuum treatment apparatus according to claim 1 wherein said single treatment-station (15) is operationally connected to a controllable source of thermal energy or to a controllable sink of thermal energy (39).

6. The vacuum treatment apparatus according to claim 1 wherein a reaction space (29) to which said workpiece carrier (17) is exposed in said single treatment-station (15) is sealed as said workpiece carrier (17) is in said treatment position (DP).

7. The vacuum treatment apparatus of claim 1 said single treatment-station (15) comprising a pumping port (33p) connectable or connected in flow communication to a pump (33).

8. The vacuum treatment apparatus of claim 1 said single treatment-station (15) being a layer deposition station.

9. The vacuum treatment apparatus of claim 1 wherein at least a part of the walls of the single treatment-station (13) exposed to said reaction space comprise an inverse-tempering arrangement (81).

10. The vacuum treatment apparatus of claim 1 whereby, in said tempering position, a sealed tempering space (21) is defined in said tempering-station (13).

11. The vacuum treatment apparatus of claim 1 said tempering-station comprising a pumping port (25p) connectable or connected to a pump (25).

12. The vacuum treatment apparatus of claim 1 comprising more than one of said station-group (11), located one behind the other, considered in said conveyance direction (W), particularly located directly one behind the other, and/or wherein particularly said more than one station-groups are equal or at least some of said more than one station-groups are different from others of said more than one station-groups, the number of said workpiece carriers (17) on said workpiece conveyer arrangement (3) being at least equal to the sum of the number of the at least one tempering-stations (13) of said more than one station-groups (11) and of the number of the one single treatment-stations (15) of said more than one station-groups (11).

13. The vacuum treatment apparatus of one of claim 1 at least one station group (11) comprising more than one of said tempering-stations (13) preceding said one single treatment-station (15), said more than one tempering-stations (13) being neighboring each other and spaced by said distance, the number of said workpiece carriers (17) on said workpiece conveyer arrangement (3) being at least equal to the sum of the number of tempering-stations (13) and of the number of single treatment-stations (15) provided.

14. The vacuum treatment apparatus of claim 1 wherein said workpiece conveyer arrangement (3) comprises at least one conveyer, driven by a forwards/backwards step-drive ((3,9)a, (3,9)ai) of said step-drive arrangement (3).

15. The coating apparatus of one of claim 1 wherein said workpiece carriers (17) are movable relative to said tempering-station (13) by said tempering-station drive (19), perpendicularly to said conveyance direction (W), towards and from the tempering position (TP).

16. The vacuum treatment apparatus of claim 15 wherein said workpiece carriers (17) are movable, by said tempering-station drive (19), perpendicularly to said conveyance direction (W) towards and from said tempering position (TP).

17. The vacuum treatment apparatus of claim 1 wherein said workpiece carriers (17) are movable by said treatment-station drive (27), relative to said single treatment-station (15), perpendicularly to said conveyance direction (W) towards and from the treatment position.

18. The vacuum treatment apparatus of claim 17 wherein said workpiece carriers (17) are movable, by said treatment-station drive (27), perpendicularly to said conveyance direction (W) towards and from said treatment position.

19. The vacuum treatment apparatus of claim 1 wherein said workpiece carriers (17) are movable by said treatment-station drive (27) and by said tempering-station drive (19), respectively, perpendicularly to said conveyance direction (W), towards and from said tempering position (TP) and towards and from said treatment position (DP) by moving said workpiece conveyer arrangement (3).

20. The vacuum treatment apparatus of claim 1 wherein said workpiece carriers (17) are movable relative to said tempering-station by said tempering-station drive (19) towards and from said tempering position (TP) by moving at least a part of said tempering-station (13) perpendicularly to said conveyance direction (W) towards and from said workpiece carrier (17).

21. The vacuum treatment apparatus of claim 1 wherein said workpiece carriers (17) are movable relative to said single treatment-station (15) by said treatment-station drive (27) towards and from said treatment position by moving at least a part of said single treatment-station (15) perpendicularly to said conveyance direction (W) towards and from said workpiece carrier (17).

22. The vacuum treatment apparatus of claim 1 wherein said workpiece carriers (17) comprise contact areas (51) for supporting a workpiece (5) which contact areas (51) provide thermal isolation of the workpiece (5) from the workpiece carrier (17).

23. The vacuum treatment apparatus of claim 1 wherein said workpiece carriers (17) and/or said workpiece conveyer arrangement (3) comprise mutual contact areas (52) which provide thermal isolation of the workpiece carrier (17) from the workpiece conveyer arrangement (3).

24. The vacuum treatment apparatus of claim 1 wherein the workpiece carriers (17) comprise a rigid, membrane-like plate (54), with at least one trough-opening (53,53p), wherein, particularly, said at least one through-opening extends over the predominant extent of said membrane-like plate (54).

25. The vacuum treatment apparatus according to claim 1 wherein said workpiece carriers (17) are frame shaped and particularly comprise trough-openings (53p) along the frame periphery.

26. The vacuum treatment apparatus of claim 1 wherein said workpiece conveyer arrangement (3) comprises a ring-shaped conveyer with a center axis or a circular disc-shaped conveyer (3d) with a center axis (Ad), which conveyer is rotated around said center axis by said step-drive arrangement (9).

27. The vacuum treatment apparatus of claim 1 wherein said workpiece conveyer arrangement (3) defines a surface of revolution (104) around a center axis (A), said step-drive arrangement (9) rotating said workpiece conveyer arrangement (3) around said center axis (A) and said workpiece carriers (17) are provided tangentially to and along said surface of revolution.

28. The vacuum treatment apparatus of claim 1 said workpiece carrier (17) in said tempering position facing, via a gap, a tempering surface (14) of said tempering-station, at least a part of said tempering surface being the surface of a heater arrangement or of a cooler arrangement (61,61b).

29. The vacuum treatment apparatus of claim 1, opposed surfaces of said workpiece carrier (17) in said tempering position facing, via a respective gap, a respective tempering surface (14,14′) of said tempering-station (13), at least a part of said tempering surfaces being surfaces of heater arrangements or of cooler arrangements (61,61b).

30. The vacuum treatment apparatus of claim 28, said one tempering surface (14) or both said tempering surfaces (14,14′) and said respective surface of said workpiece carrier being spaced via said respective gap by an averaged distance d for which there is valid:
0.1 mm≤d≤30 mm,
particularly 0.1 mm≤d≤5 mm.

31. The vacuum treatment apparatus of claim 1 a sealed tempering space (21) being defined in said tempering-station (13) and in said tempering position, said tempering-station comprising a gas-feed line arrangement (65) dispatching into said tempering space (21).

32. The vacuum treatment apparatus of claim 31, said tempering space (21) comprising no pumping port, a flow communication from said tempering space to a pumping port being established by unsealing said tempering space thereby establishing a gas-flow communication of negligible flow resistance out of said tempering space.

33. The vacuum treatment apparatus of claim 1, said tempering-station (13) comprising a pumping port.

34. The vacuum treatment apparatus of claim 31 said gas-feed line arrangement (65) being in flow connection with a gas supply (73) particularly containing at least one of helium, hydrogen, argon.

35. The vacuum treatment apparatus of claim 31 comprising a gas-heater or a gas-cooler (69) interconnected between said tempering space (21) and said gas supply (73), along said gas-feed line arrangement (65).

36. The vacuum treatment apparatus of claim 1 said single treatment-station (15) comprising a gas feed arrangement (35) for a reactive gas which gas feed arrangement comprising an input line (100) dispatching in said reaction space (29), an input to said input line (100) branching via a controllable valve arrangement (99a,99b) to at least two gas supply sources (97a,97b) containing reactive gas.

37. The vacuum treatment apparatus of claim 1 wherein said single treatment-station (15) comprises a gas feed arrangement (35) connectable or connected in gas-flow communication with a gas supply (37) containing a reactive gas which reactive gas comprises or consists of a monomer gas with a characteristic according to which said monomer gas polymerizes on a surface with an increasing polymerization rate as the temperature of said surface decreases.

38. The vacuum treatment apparatus of claim 1 wherein said single treatment-station (15) comprises a gas feed arrangement (35) connectable or connected in gas-flow communication with a gas supply (37) containing a reactive gas which reactive gas does not comprise or does not consist of a monomer gas with a characteristic according to which said monomer gas polymerizes on a surface with an increasing polymerization rate as the temperature of said surface decreases.

39. A method of vacuum-process treating surfaces of workpieces or of manufacturing workpieces having a vacuum-process treated surface, comprising:
a) feeding a workpiece into a vacuum atmosphere;
b) conveying said workpiece into a tempering position in an evacuated tempering-station;
c) tempering said workpiece during a tempering time span in said tempering position by heating or by cooling a surface of said workpiece to a predetermined first temperature;
d) conveying said tempered workpiece in vacuum into a treatment position in an evacuated treatment-station;
e) treating said surface of said workpiece during a treatment time span in said treating position thereby exposing said surface to a second temperature;
f) removing said workpiece from said treatment-station,
thereby
selecting said first temperature so that said workpiece, after being conveyed into said treatment position, exhibits a surface temperature, which is different from said second temperature by a desired, selected amount, and selecting said tempering time span to be equal to said treatment time span.

40. The method of claim 39 comprising selecting said amount to be at least 50° C.

41. The method of claim 39 comprising selecting said amount to be at least 100° C.

42. The method of claim 39 comprising performing in said step c) said tempering by more than one consecutive tempering steps, each of said tempering steps lasting during said tempering time span.

43. The method of claim 39 comprising repeating steps b) to e) at least once.

44. The method of claim 39 comprising a step g) between said step b) and said step c) said step g) comprising sealing a tempering pace in said tempering-station to which said surface of said workpiece is exposed.

45. The method of claim 44 wherein said step g) comprises pressurizing said tempering space after said sealing of said tempering space.

46. The method of claim 45 comprising a step h) between said step c) and said step d), said step h) comprising depressurizing said tempering space, particularly by pumping, particularly by directly pumping said tempering space.

47. The method of claim 39 comprising a step i) between said step d) and said step e) said step i) comprising sealing a reaction space in said treatment-station to which said surface of said workpiece is exposed.

48. The method of claim 47 wherein said step i) comprises feeding a reactive gas into said reaction space after said sealing of said reaction space.

49. The method of claim 39 comprising, at least during said step e), inverse tempering of wall surfaces of said treatment-station which are exposed to said reaction space.

50. The method of claim 39 performed by making use of a vacuum treatment apparatus comprising
a vacuum recipient (1);
a workpiece conveyer arrangement (3) in said vacuum recipient, driven by a controlled step-drive arrangement (9) in a conveyance direction (W) and comprising at least two workpiece carriers (17);
at least one station-group (11) coupled to said vacuum recipient (1) and consisting of at least one tempering-station (13) and of one single treatment-station (15), said one single treatment-station (15) being located subsequent said at least one tempering-station (13) in said conveyance direction, said at least one tempering-station (13) and said one single treatment-station (15) being mutually spaced by a distance in said conveyance direction (W);
said workpiece conveyer arrangement (3) and said step-drive arrangement (9) being constructed to convey said workpiece carriers (17) by one or more than one steps in said conveyance direction (W) simultaneously and thereby simultaneously into alignment with said at least one tempering-station (13) and with said one single treatment-station (15);
each of said at least two workpiece carriers (17) being movable by a tempering-station drive (19) into and from a tempering position (TP) relative to said one single tempering-station (13), once aligned with said tempering-station;
each of said at least two workpiece carriers (17) being movable by a treatment-station drive (27) into and from a treatment position (DP) relative to said one single treatment-station (15), once aligned with said one single treatment-station,
said at least one tempering-station being configured to heat or to cool a workpiece in said tempering-station to such a temperature that said heated or cooled workpiece, once conveyed from said at least one tempering-station into said treatment-station, enters said treatment-station with a surface temperature which is different from the temperature said surface is exposed to in said treatment-station by a desired, selected amount.

51. The method of claim 39 comprising performing a step i) between said step d) and said step e), said step i) comprising feeding a reactive gas into said reaction space after said sealing of said reaction space, said reaction gas comprising or consisting of a monomer gas with a characteristic according to which said monomer gas polymerizes on a surface with an increasing polymerization rate as the temperature of said surface decreases.

52. The method of claim 39 comprising performing a step i) between said step d) and said step e), said step i) comprises feeding a reactive gas into said reaction space after said sealing of said reaction space, said reactive gas not comprising or not consisting of a monomer gas with a characteristic according to which the monomer gas polymerizes on a surface with an increasing polymerization rate as the temperature of said surface decreases.
